(19) United States
(12) Patent Application Publication
(10) Pub. No.: US 2019/0027378 A1
(43) Pub. Date: Jan. 24, 2019

(54) METHODS OF FABRICATING PACKAGE SUBSTRATES HAVING EMBEDDED CIRCUIT PATTERNS

(71) Applicant: SK hynix Inc., Icheon-si Gyeonggi-do (KR)

(72) Inventors: Myeong Seob KIM, Icheon-si Gyeonggi-do (KR); Jae Young KIM, Gunpo-si Gyeonggi-do (KR); Ki Ill MOON, Seoul (KR)

(73) Assignee: SK hynix Inc., Icheon-si Gyeonggi-do (KR)

(21) Appl. No.: 16/143,103

(22) Filed: Sep. 26, 2018

Related U.S. Application Data
(62) Division of application No. 14/990,144, filed on Jan. 7, 2016.

(30) Foreign Application Priority Data
Aug. 20, 2015 (KR) 10-2015-0117456

(51) Int. Cl. H01L 21/48

(52) U.S. Cl. CPC H01L 21/4857; H01L 23/49816

(57) ABSTRACT

There is provided a method of fabricating a package substrate. The method may include forming an isolation trench in a conductive layer, and forming a first dielectric layer on the conductive layer to provide an isolation wall portion filling the isolation trench. The method may include recessing the conductive layer to form circuit patterns in circuit trenches defined and separated by the isolation wall portion. The method may include forming a second dielectric layer covering the circuit patterns, and patterning the first and second dielectric layers to expose portions of the circuit patterns. The exposed portions of the circuit patterns may act as connectors.

### CROSS-REFERENCE TO RELATED APPLICATION

The present application is a Division of U.S. patent application Ser. No. 14/990,144, filed on Jan. 7, 2016 and the present application claims priority under 35 U.S.C 119(a) to Korean Patent Application No. 10-2015-0117456, filed on Aug. 20, 2015, in the Korean Intellectual Property Office, which is incorporated herein by reference in its entirety.

### BACKGROUND

### 1. Technical Field

Embodiments of the present disclosure generally relate to semiconductor package technologies and, more particularly, to package substrates having embedded circuit patterns, methods of fabricating the same, and semiconductor packages including the same.

### 2. Related Art

Semiconductor packages capable of processing a large amount of data are increasingly in demand with the development of smaller electronic systems such as mobile systems. As a result, package substrates including circuit patterns having a fine pitch size have been required. Electronic devices, for example, semiconductor chips may be mounted on the package substrates. Package substrates may include for example printed circuit boards (PCBs). Each of the package substrates may be fabricated by depositing a conductive layer on a substrate body and by etching the conductive layer with a subtractive process to form circuit patterns. In such a case, the circuit patterns may be formed to have non-uniform widths. That is, it may be difficult to accurately or uniformly control a pitch size of the circuit patterns. Accordingly, a lot of effort has been focused on developing methods of forming fine circuit patterns having a uniform pitch size.

### BRIEF DESCRIPTION OF THE DRAWINGS

FIGS. 1 to 16 are cross-sectional views illustrating examples of representations of a method of fabricating a package substrate according to an embodiment.

FIGS. 17 and 18 are cross-sectional views illustrating examples of representations of semiconductor packages including a package substrate according to an embodiment.

FIGS. 19 to 29 are cross-sectional views illustrating examples of representations of a method of fabricating a package substrate according to an embodiment.

FIGS. 30 and 31 are cross-sectional views illustrating examples of representations of semiconductor packages including a package substrate according to an embodiment.

FIG. 32 is a block diagram illustrating an example of a representation of an electronic system employing a memory card including a package according to an embodiment.

FIG. 33 is a block diagram illustrating an example of a representation of an electronic system including a package according to an embodiment.

### DETAILED DESCRIPTION

Various embodiments may be directed to package substrates having embedded circuit patterns, methods of fabricating the same, semiconductor packages including the same, electronic systems including the same, and memory cards including the same.

According to an embodiment, there is provided a method of fabricating a package substrate. The method may include forming an isolation trench in a conductive layer, forming a first dielectric layer on the conductive layer to provide an isolation wall portion filling the isolation trench, recessing the conductive layer to form circuit patterns in circuit trenches defined and separated by the isolation wall portion, forming a second dielectric layer covering the circuit patterns, and patterning the first and second dielectric layers to expose portions of the circuit patterns. The exposed portions of the circuit patterns may act as connectors.

According to an embodiment, there is provided a method of fabricating a package substrate. The method may include forming a first conductive layer on a front side surface and a back side surface of a carrier layer, forming an isolation trench in the first conductive layer, forming a first dielectric layer on the first conductive layer to provide an isolation wall portion filling the isolation trench, forming a second conductive layer on the first dielectric layer, separating a stack structure including the first conductive layer, the first dielectric layer and the second conductive layer sequentially stacked on each of the front and back side surfaces of the carrier layer from the carrier layer, recessing the first conductive layer of the stack structure to form first circuit patterns in circuit trenches defined and separated by the isolation wall portion, and patterning the second conductive layer of the stack structure to form second circuit patterns.

According to an embodiment, there is provided a method of fabricating a package substrate. The method may include forming an isolation trench in a conductive layer, forming a first dielectric layer on the conductive layer to provide an isolation wall portion filling the isolation trench, recessing the conductive layer to form circuit patterns in circuit trenches defined and separated by the isolation wall portion, forming a second dielectric layer covering the circuit patterns, and patterning the first and second dielectric layers to expose portions of the circuit patterns. The exposed portions of the circuit patterns may act as connectors.

According to another embodiment, there is provided a method of fabricating a package substrate. The method may include forming a conductive layer on a front side surface and a back side surface of a carrier layer, forming an isolation trench in the conductive layer, forming a first dielectric layer on the conductive layer to provide an isolation wall portion filling the isolation trench, separating a stack structure including the conductive layer and the first dielectric layer sequentially stacked on each of the front and back side surfaces of the carrier layer from the carrier layer, recessing the conductive layer of the stack structure to form circuit patterns in circuit trenches defined and separated by the isolation wall portion, forming a second dielectric layer covering the circuit patterns, and patterning the first and second dielectric layers to expose portions of the circuit patterns. The exposed portions of the circuit patterns may act as connectors.

According to an embodiment, a package substrate may include a first dielectric layer having a body portion and an isolation wall portion protruding from a surface of the body portion, first circuit patterns disposed in circuit trenches defined and separated by the isolation wall portion, and second circuit patterns disposed on a surface of the first dielectric layer opposite to the first circuit patterns.

According to an embodiment, a semiconductor package may include a package substrate and a semiconductor device mounted on the package substrate. The package substrate may include a first dielectric layer having a body portion and an isolation wall portion protruding from a surface of the body portion, first circuit patterns disposed in circuit trenches defined and separated by the isolation wall portion, and second circuit patterns disposed on a surface of the first dielectric layer opposite to the first circuit patterns.

According to an embodiment, a package substrate may include a first dielectric layer having a body portion and an isolation wall portion protruding from a surface of the body portion, circuit patterns disposed in circuit trenches defined and separated by the isolation wall portion, and a second dielectric layer laminated on the isolation wall portion of the first dielectric layer to cover the circuit patterns. The first and second dielectric layers may be disposed to expose connectors corresponding to portions of the circuit patterns.

According to an embodiment, a semiconductor package may include a package substrate and a semiconductor device mounted on the package substrate. The package substrate may include a first dielectric layer having a body portion and an isolation wall portion protruding from a surface of the body portion, circuit patterns disposed in circuit trenches defined and separated by the isolation wall portion, and a second dielectric layer laminated on the isolation wall portion of the first dielectric layer to cover the circuit patterns. The first and second dielectric layers may be disposed to expose connectors corresponding to portions of the circuit patterns.

According to an embodiment, there is provided a memory card including a semiconductor package. The semiconductor package may include a package substrate and a semiconductor device mounted on the package substrate. The package substrate may include a first dielectric layer having a body portion and an isolation wall portion protruding from a surface of the body portion, first circuit patterns disposed in circuit trenches defined and separated by the isolation wall portion, and second circuit patterns disposed on a surface of the first dielectric layer opposite to the first circuit patterns.

According to an embodiment, there is provided a memory card including a semiconductor package. The semiconductor package may include a package substrate and a semiconductor device mounted on the package substrate. The package substrate may include a first dielectric layer having a body portion and an isolation wall portion protruding from a surface of the body portion, circuit patterns disposed in circuit trenches defined and separated by the isolation wall portion, and a second dielectric layer laminated on the isolation wall portion of the first dielectric layer to cover the circuit patterns. The first and second dielectric layers may be disposed to expose connectors corresponding to portions of the circuit patterns.

According to an embodiment, there is provided an electronic system including a semiconductor package. The semiconductor package may include a package substrate and a semiconductor device mounted on the package substrate. The package substrate may include a first dielectric layer having a body portion and an isolation wall portion protruding from a surface of the body portion, first circuit patterns disposed in circuit trenches defined and separated by the isolation wall portion, and second circuit patterns disposed on a surface of the first dielectric layer opposite to the first circuit patterns.

According to an embodiment, there is provided an electronic system including a semiconductor package. The semiconductor package may include a package substrate and a semiconductor device mounted on the package substrate. The package substrate may include a first dielectric layer having a body portion and an isolation wall portion protruding from a surface of the body portion, circuit patterns disposed in circuit trenches defined and separated by the isolation wall portion, and a second dielectric layer laminated on the isolation wall portion of the first dielectric layer to cover the circuit patterns. The first and second dielectric layers may be disposed to expose connectors corresponding to portions of the circuit patterns.

According to an embodiment, there is provided a package substrate. The package substrate may include a first dielectric layer having a body portion and an isolation wall portion protruding from a surface of the body portion, first circuit patterns disposed in circuit trenches defined by the isolation wall portion, and second circuit patterns disposed on a surface of the first dielectric layer opposite to the first circuit patterns.

According to an embodiment, there is provided a method of fabricating a package substrate. The method may include forming a first dielectric layer having a body portion and an isolation wall portion protruding from a surface of the body portion, forming circuit patterns in circuit trenches defined by the isolation wall portion, and forming second circuit patterns on a surface of the first dielectric layer opposite to the first circuit patterns.

According to an embodiment, there is provided a semiconductor package including a package substrate and a semiconductor device mounted on the package substrate. The package substrate may include a first dielectric layer having a body portion and an isolation wall portion protruding from a surface of the body portion, first circuit patterns disposed in circuit trenches defined by the isolation wall portion, and second circuit patterns disposed on a surface of the first dielectric layer opposite to the first circuit patterns.

According to an embodiment, there is provided a method of fabricating a package substrate. The method may include forming a first dielectric layer having a body portion and an isolation wall portion protruding from a surface of the body portion, forming first circuit patterns disposed in circuit trenches defined by the isolation wall portion, and forming second circuit patterns disposed on a surface of the first dielectric layer opposite to the first circuit patterns.

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the concepts.

A semiconductor package may include a semiconductor device. The semiconductor device may include a single semiconductor chip or a plurality of semiconductor chips which are stacked. The semiconductor chips may be obtained by separating a semiconductor substrate such as a wafer into a plurality of pieces using a die sawing process. The semiconductor chips may correspond to memory chips or logic chips. The memory chips may include dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The logic chip may include logic circuits which are integrated on the semiconductor substrate. The semiconductor package may be employed in communication systems such as mobile phones, electronic systems associated with biotechnology or health care, or wearable electronic systems.

Same reference numerals refer to same elements throughout the specification. Thus, even though a reference numeral is not mentioned or described with reference to a drawing, the reference numeral may be mentioned or described with reference to another drawing. In addition, even though a reference numeral is not illustrated in a drawing, it may be mentioned or described with reference to another drawing.

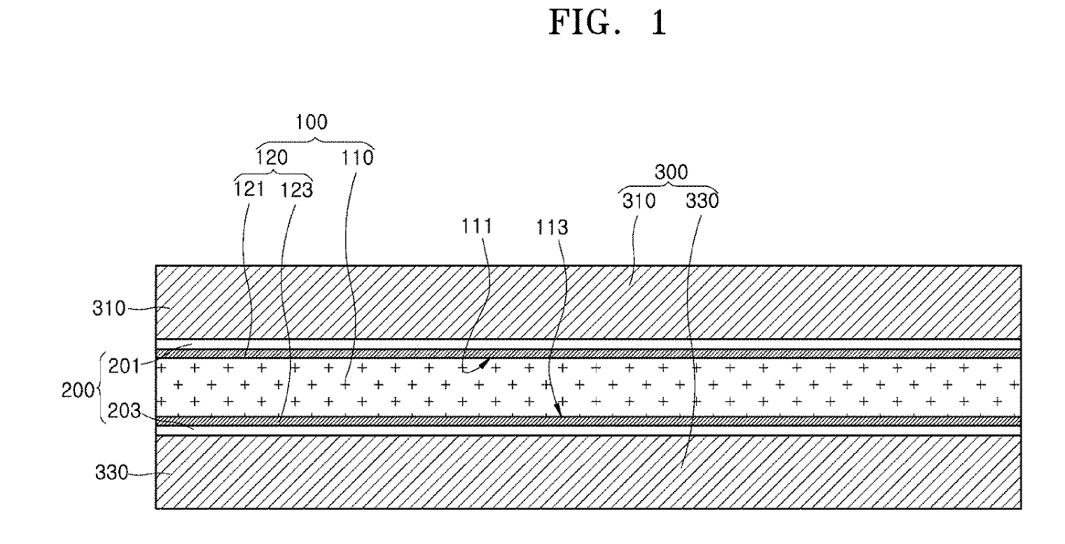

FIGS. 1 to 16 are cross-sectional views illustrating examples of representations of a method of fabricating a package substrate according to an embodiment.

FIG. 1 illustrates a step of forming a first conductive layer 300 on a carrier layer 100.

Referring to FIG. 1, a structure that the first conductive layer 300 is stacked on the carrier layer 100 may be provided. The carrier layer 100 may function as a support substrate or a subsidiary substrate for supporting and handling the first conductive layer 300 during subsequent processes. In order to improve a fabrication efficiency of the package substrate, the first conductive layer 300 may include two layers 310 and 330 that are respectively disposed on two opposite surfaces of the carrier layer 100. For example, the first conductive layer 300 may include a first front side conductive layer 310 disposed on a front side surface of the carrier layer 100 and a first back side conductive layer 330 disposed on a back side surface of the carrier layer 100.

The first conductive layer 300 may be formed to include copper or copper alloy. The first conductive layer 300 may be formed by attaching a conductive foil to one surface or two opposite surfaces of the carrier layer 100. The carrier layer 100 may include a copper clad laminate (CCL) structure. The CCL structure may be used as a base layer or a sheet layer that is utilized in fabrication of the package substrate such as a double-layered printed circuit board (PCB).

The CCL structure may have a structure that a couple of conductive clad layers 120 are respectively laminated on two opposite surfaces 111 and 113 of an insulation core layer 110. The insulation core layer 110 may include a resin material or a composite material formed of a fabric material containing resin. The fabric material may include glass fiber or glass fabric. The conductive clad layers 120 may include a first conductive clad layer 121 laminated on a first surface 111 of the insulation core layer 110 and a second conductive clad layer 123 laminated on a second surface 113 of the insulation core layer 110 opposite to the first conductive clad layer 121. The conductive clad layers 120 may be formed to include copper or copper alloy. In general, the CCL structure may be used as a main substrate in fabrication of a package substrate. However, according to an embodiment, the CCL structure may be used as a subsidiary substrate or the carrier layer 100 for supporting the first conductive layer 300. Thus, another support substrate having a structure other than the CCL structure may also be used as the carrier layer 100.

The first conductive layer 300 may be formed by attaching a conductive foil to the carrier layer 100. For example, the first conductive layer 300 may be formed by laminating a copper foil or a copper alloy foil on the carrier layer 100 having the CCL structure. An adhesive layer 200 may be formed between the first conductive layer 300 (i.e., the copper foil or the copper alloy foil) and the carrier layer 100 (i.e., the CCL structure) to laminate the copper foil or the copper alloy foil on the CCL structure. The adhesive layer 200 may be formed to a thickness of about a few micrometers to about several tens of micrometers. The adhesive layer 200 may include a first adhesive layer 201 formed on the first conductive clad layer 121 and a second adhesive layer 203 formed on the second conductive clad layer 123. In such a case, the first front side conductive layer 310 may be attached to the carrier layer 100 using the first adhesive layer 201, and the first back side conductive layer 330 may be attached to the carrier layer 100 using the second adhesive layer 203.

The first conductive layer 300 may be formed to provide circuit patterns of the package substrate. The first conductive layer 300 may be formed to have a thickness which is greater than a thickness of the circuit patterns that are formed in a subsequent process. That is, the first conductive layer 300 may be etched back and patterned to form the circuit patterns in a subsequent process. As a result, a thickness of the circuit patterns may be less than a thickness of the first conductive layer 300.

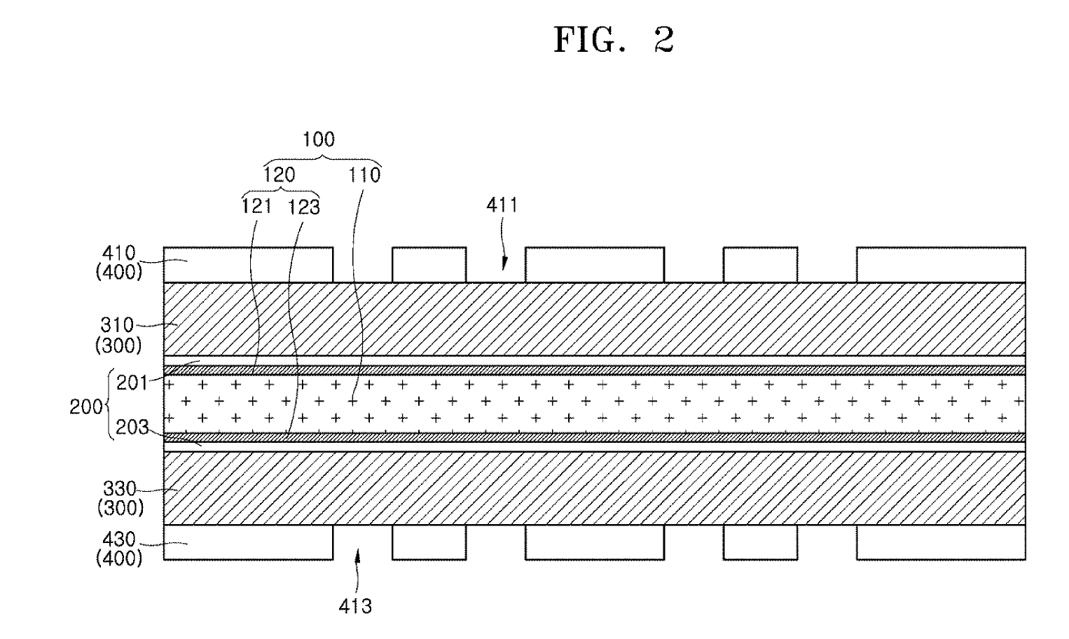

FIG. 2 illustrates a step of forming a first etch mask 400 on the first conductive layer 300.

Referring to FIG. 2, the first etch mask 400 may be formed to expose portions of the first conductive layer 300. The first etch mask 400 may be formed by laminating a dry film on the first conductive layer 300 to expose portions of the first conductive layer 300. The first etch mask 400 may be formed to include a first front side etch mask 410 having first openings 411 that expose portions of the first front side conductive layer 310 and a first back side etch mask 430 having second openings 413 that expose portions of the first back side conductive layer 330.

The first openings 411 may be located to vertically overlap with the second openings 413, respectively. Accordingly, the first front side etch mask 410 may be formed to have the same shape as the first back side etch mask 430. In contrast, the first front side etch mask 410 may be formed to have a different shape from the first back side etch mask 430. In such a case, circuit patterns which are formed on the first conductive clad layer 121 in a subsequent process may have a different shape from circuit patterns which are formed on the second conductive clad layer 123 in a subsequent process.

The first etch mask 400 may be formed to have the same pattern image as the circuit patterns which are realized in a subsequent process. Thus, the first and second openings 411 and 413 may be formed to exhibit a reverse image of the circuit patterns which are realized in a subsequent process. That is, the first and second openings 411 and 413 may be formed to have the same planar shape as a region between the circuit patterns.

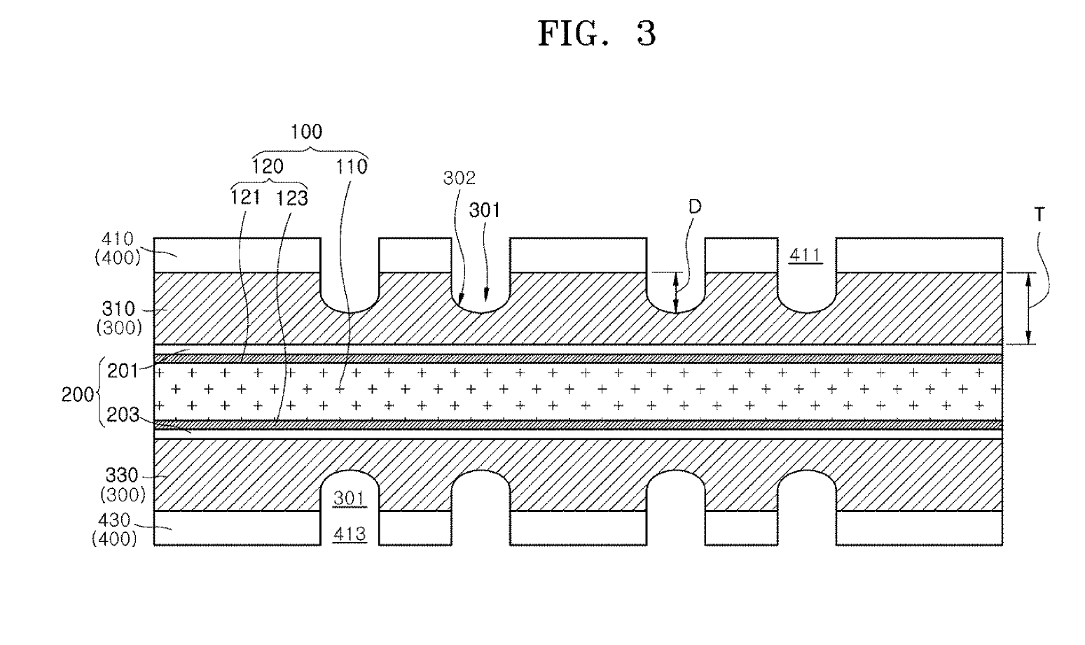

FIG. 3 illustrates a step of forming an isolation trench 301 in the first conductive layer 300.

Referring to FIG. 3, the first conductive layer 300 exposed by the first and second openings 411 and 413 of the first etch mask 400 may be etched to form the isolation trench 301. As described above, the first and second openings 411 and 413 may have the same planar shape as the region between the circuit patterns. Thus, the isolation trench 301 may be formed in order to separate the circuit patterns from each other.

The isolation trench 301 may be formed to have a depth D which is less than a thickness T of the first conductive layer 300. That is, the isolation trench 301 may be formed not to penetrate the first conductive layer 300 so that a portion of the first conductive layer 300 remains below a bottom surface of the isolation trench 301. In order to form the isolation trench 301, the first conductive layer 300 may be etched using a partial etch process, for example, a half etch process not to expose the first and second conductive clad layers 121 and 123. The etch process for forming the isolation trench 301 may be performed using a wet etch process for removing a copper material. In such a case, the depth D of the isolation trench 301 may be controlled by adjusting an etch time of the wet etch process or a concentration of an etchant used in the wet etch process. If the isolation trench 301 is formed using the wet etch process, the first conductive layer 300 may be isotropically etched. Accordingly, the isolation trench 301 may be formed to have a rounded bottom surface, as illustrated in FIG. 3. That is, the isolation trench 301 may be formed to have a circular shaped bottom surface or a concave bottom surface.

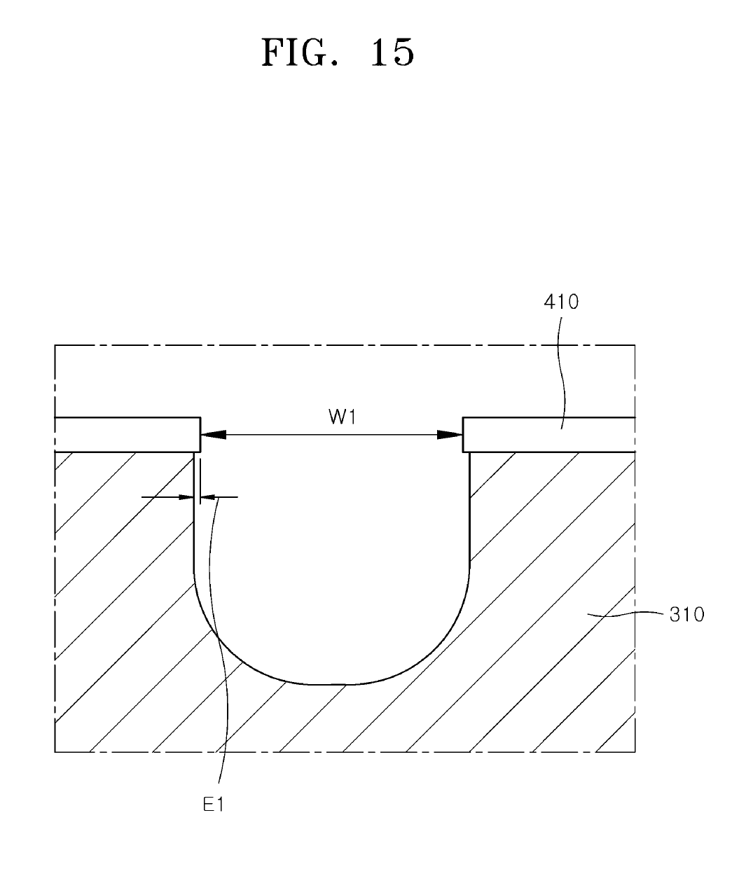

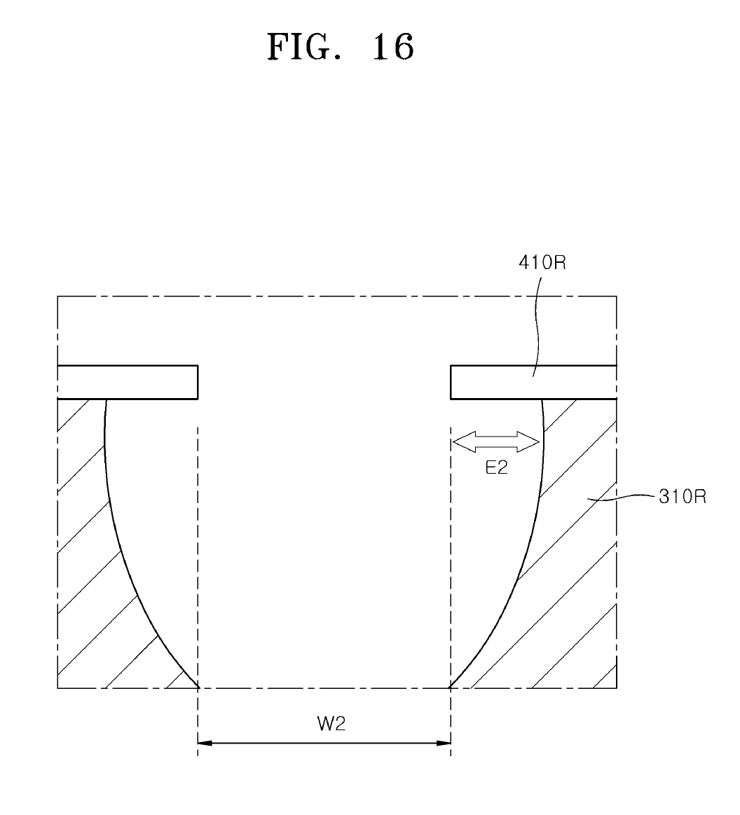

Referring to FIGS. 3 and 15, when the first front side conductive layer 310 exposed by the first front side etch mask 410 is etched using an isotropic etch process such as a wet etch process, a width of the isolation trench 301 may be greater than a width W1 of the first opening 411 by twice a width E1. That is, if the first front side conductive layer 310 exposed by the first front side etch mask 410 is isotropically etched, an undercut region having the width E1 may be formed below an edge of the first front side etch mask 410 adjacent to the first opening 411. The width E1 of the undercut region may increase as the etch time elapses. For example, as illustrated in FIG. 16, if a conductive layer 310R exposed by an etch mask 410R is isotropically and fully etched until a trench completely penetrating the conductive layer 310R is formed, an undesired undercut region having a width E2 may be formed below an edge of the etch mask 410R. In such a case, if a thickness of the conductive layer 310R is equal to a thickness of the first front side conductive layer 310 and an opening of the etch mask 410R has a width W2, the width E2 of the undercut region may be greater than the width E1 of the undercut illustrated in FIG. 15. This is because an amount of a laterally etched conductive layer 310R during the full etch process is greater than an amount of a laterally etched first front side conductive layer 310 during the half etch process.

As illustrated in FIGS. 3 and 15, the half etch process for forming the isolation trench 301 may be performed so that a portion of the first conductive layer 300 remains under the isolation trench 301 to have a concave shape. If the isolation trench 301 is formed using the half etch process, the half etch process may prevent the first conductive layer 300 from being laterally over-etched. That is, the half etch process may reduce a difference between a width of the opening 411 or 413 of the first etch mask 400 and a width of the isolation trench 301. Accordingly, a variation of the width of the isolation trench 301 may be reduced to provide uniform and fine circuit patterns.

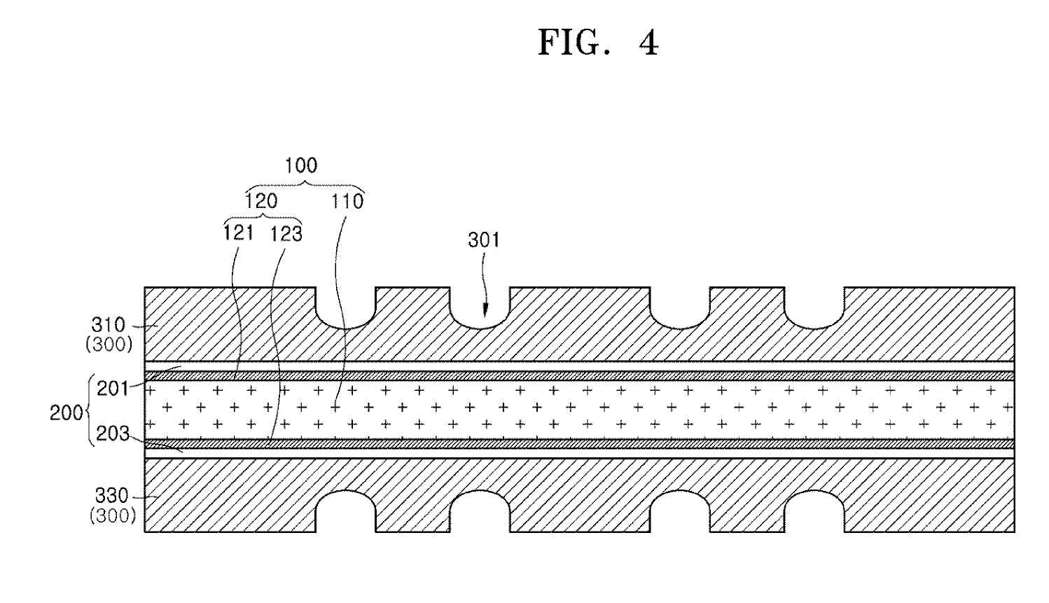

FIG. 4 illustrates a step of exposing the first conductive layer 300.

Referring to FIG. 4, after the isolation trench 301 is formed in the first conductive layer 300 to have a dented shape, the first etch mask (400 of FIG. 3) may be removed. That is, the dry film used as the first etch mask 400 may be striped to expose an entire surface of the first conductive layer 300.

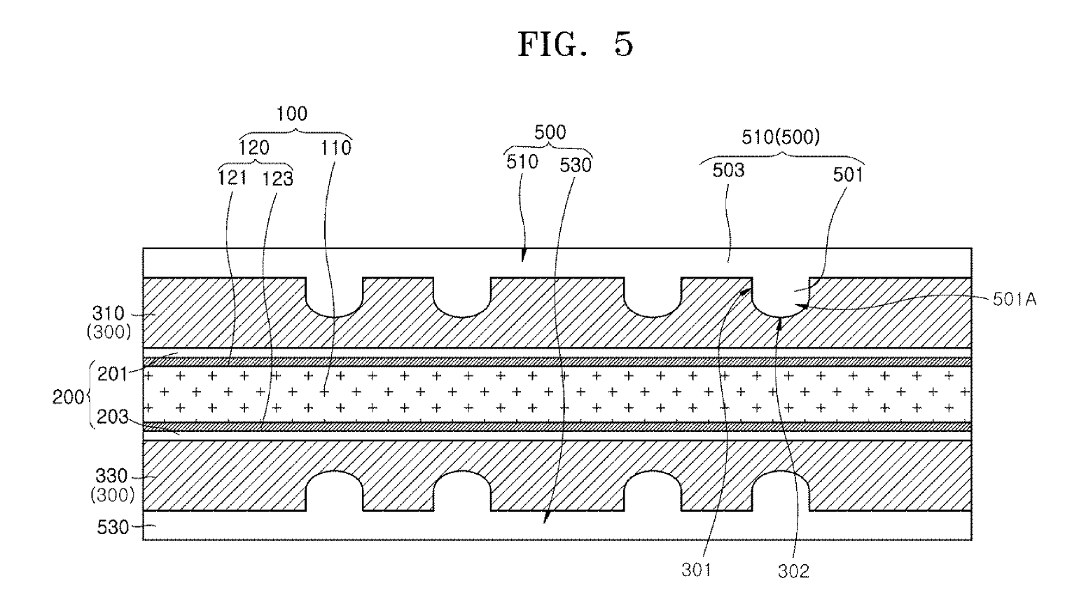

FIG. 5 illustrates a step of forming a first dielectric layer 500.

Referring to FIG. 5, the first dielectric layer 500 may be formed on the first conductive layer 300 to fill the isolation trench 301. The first dielectric layer 500 may be formed to provide a body of an insulation portion of the package substrate. The first dielectric layer 500 may include an isolation wall portion 501 filling the isolation trench 301. Since the isolation wall portion 501 is formed to fill the isolation trench 301, the isolation wall portion 501 may include a convex portion 501a filling a concave portion 302 of the isolation trench 301. Because the convex portion 501a fills the concave portion 302 of the isolation trench 301, the convex portion 501a may have a convex surface. The first dielectric layer 500 may also include a body portion 503 that extends from the isolation wall portion 501 to cover a top surface of the first conductive layer 300. The isolation wall portion 501 may have a protrusion shape that substantially protrudes from a surface of the body portion 503. The first conductive layer 300 may be located between the adjacent isolation wall portions 501.

The first dielectric layer 500 may be formed by stacking a prepreg layer on the first conductive layer 300 with a lamination process. The prepreg layer may include a resin material such as an epoxy material or may include a reinforced fiber material matrix containing a resin material. The first dielectric layer 500 may include a first front side dielectric layer 510 formed on the first front side conductive layer 310 and a first back side dielectric layer 530 formed on the first back side conductive layer 330. The first front side dielectric layer 510 and the first back side dielectric layer 530 may be simultaneously formed on two opposite surfaces of the carrier layer 100, respectively.

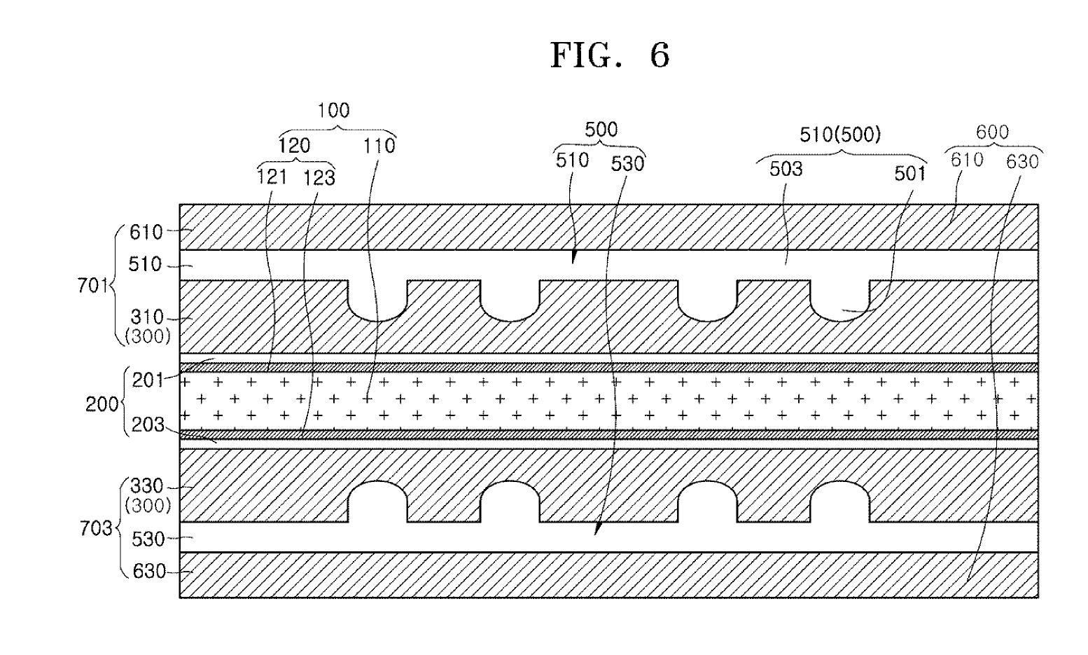

FIG. 6 illustrates a step of forming a second conductive layer 600 on the first dielectric layer 500.

Referring to FIG. 6, the second conductive layer 600 may be formed on the first dielectric layer 500 using a lamination process to provide a stack structure that the first dielectric layer 500 is sandwiched between the first and second conductive layers 300 and 600. The second conductive layer 600 may be formed by stacking a copper foil or a copper alloy foil on the first dielectric layer 500 using a lamination process. In some embodiments, a prepreg layer and a copper foil may be sequentially stacked on the first conductive layer 300, and the prepreg layer and the copper foil may be laminated on the first conductive layer 300 to form the first dielectric layer 500 and the second conductive layer 600. The second conductive layer 600 may include a second front side conductive layer 610 formed on the first front side dielectric layer 510 and a second back side conductive layer 630 formed on the first back side dielectric layer 530.

As a result of the above processes, a first stack structure 701 including the first front side conductive layer 310, the first front side dielectric layer 510 and the second front side conductive layer 610, which are sequentially stacked, may be provided on one surface of the carrier layer 100. In addition, a second stack structure 703 including the first back side conductive layer 330, the first back side dielectric layer 530 and the second back side conductive layer 630, which are sequentially stacked, may be provided on another surface of the carrier layer 100. That is, the first and second stack structures 701 and 703 may be respectively formed on two opposite surfaces of the carrier layer 100 and may be symmetric with respect to the carrier layer 100 to provide a mirror structure.

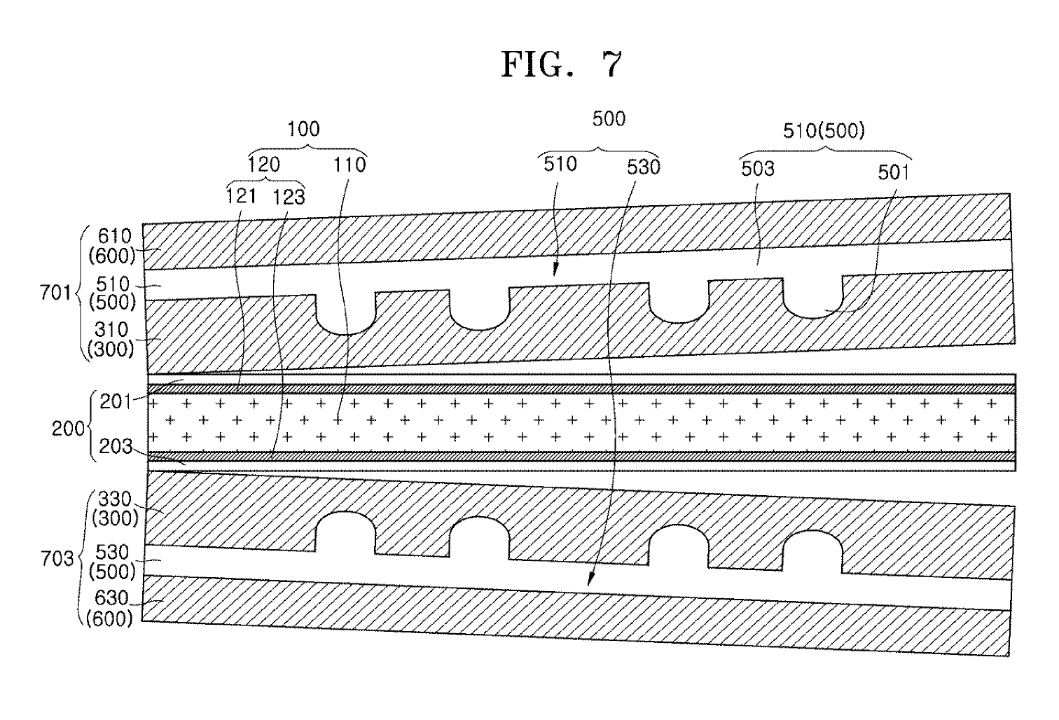

FIG. 7 illustrates a step of separating the first and second stack structures 701 and 703 from the carrier layer 100.

Referring to FIG. 7, the first and second stack structures 701 and 703 may be peeled from one edge of the carrier layer 100 and may be completely separated from the carrier layer 100. Since an adhesive strength between the adhesive layer 200 and the first conductive layer 300 is greater than an adhesive strength between the adhesive layer 200 and the conductive clad layer 120, the first and second stack structures 701 and 703 may be readily separated from the carrier layer 100. Each of the first and second stack structures 701 and 703 separated from the carrier layer 100 may be used as a panel for providing a package substrate. Because the first and second stack structures 701 and 703 have the same configuration, each of the first and second stack structures 701 and 703 may be treated by the same processes as described hereinafter.

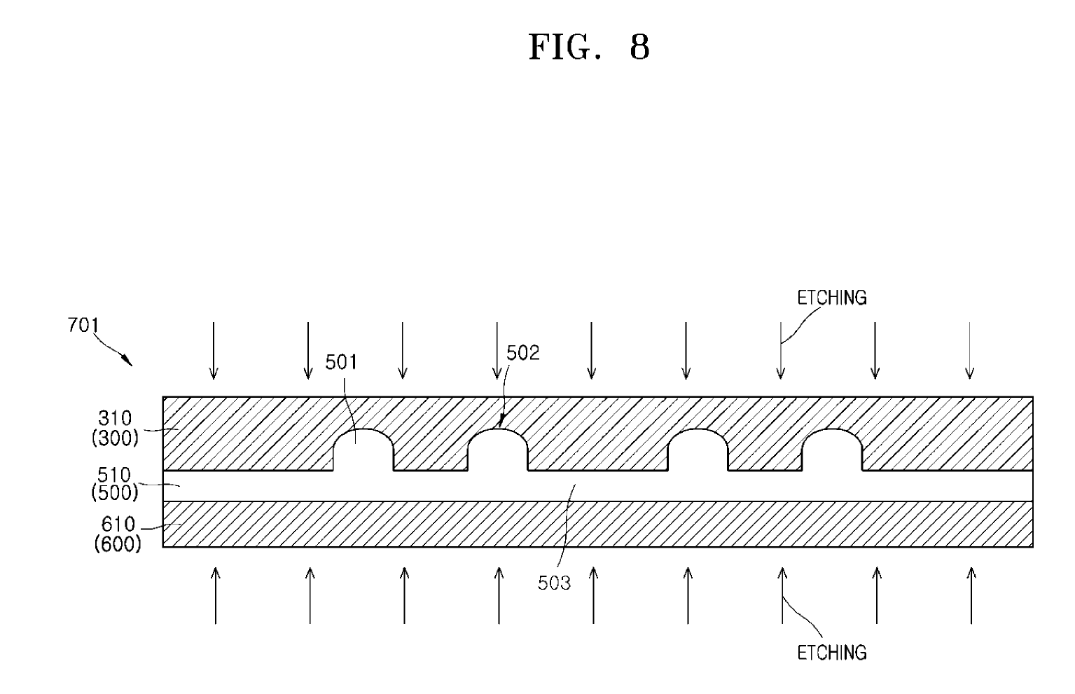

FIG. 8 illustrates a step of recessing the first conductive layer 300.

Referring to FIG. 8, the first conductive layer 300 may be recessed by a blanket etch-back process to reduce a thickness of the first conductive layer 300. The blanket etch-back process may be performed using a wet etch process. While the first conductive layer 300 is recessed by a blanket etch-back process, the second conductive layer 600 may also be recessed by the blanket etch-back process. The blanket etch-back process for recessing the first and second conductive layers 300 and 600 may be performed using a half etch process to partially remove the first and second conductive layers 300 and 600. A thickness of the etched conductive layers 300 and 600 may be controlled by adjusting an etch time of the blanket etch-back process or a concentration of an etchant used in the blanket etch-back process. That is, a thickness of the remaining conductive layers 300 and 600 may be appropriately controlled by adjusting an etch time of the blanket etch-back process or a concentration of an etchant used in the blanket etch-back process.

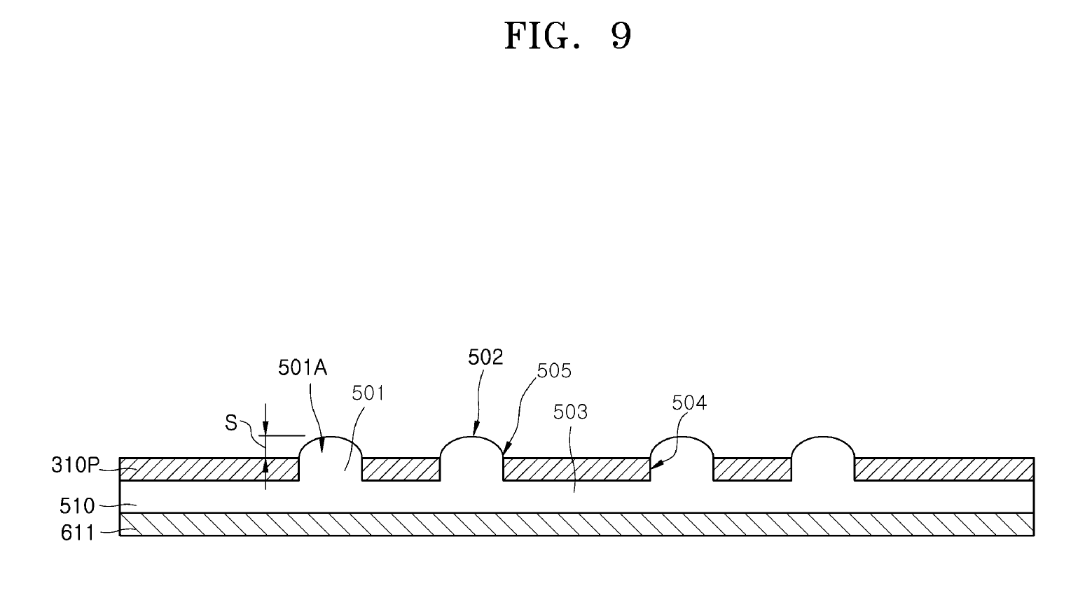

FIG. 9 illustrates a step of forming first circuit patterns 310P.

Referring to FIG. 9, the blanket etch-back process for recessing the first conductive layers 300 may be performed until a top surface 502 of an upper portion of the isolation wall portion 501 is exposed. The upper portion of the isolation wall portion 501 may correspond to the convex portion 501a of the isolation wall portion 501, and the convex portion 501a may fill the concave portion 302 of the isolation trench (301 of FIG. 5) to have the convex top surface. Accordingly, the first conductive layers 300 may be recessed by the blanket etch-back process until the convex portion 501a is exposed. In some embodiments, the first conductive layers 300 may be recessed by the blanket etch-back process until upper portions 505 of sidewalls of the isolation wall portion 501 are exposed.

Even after the top surface 502 of the isolation wall portion 501 is exposed, the first conductive layer 300 may be additionally recessed to form the plurality of first circuit patterns 310P which are comprised of the first conductive layer 300 and separated from each other. That is, the first circuit patterns 310P may correspond to remaining portions of the first conductive layer 300 which are separated from each other by the isolation wall portion 501.

The blanket etch-back process for recessing the first conductive layers 300 may include an over-etch step that is performed so that a certain level difference S exists between the top surface 502 of the isolation wall portion 501 and a top surface of each of the first circuit patterns 310P. That is, the top surfaces of the first circuit patterns 310P may be located at a level which is lower than the top surface 502 of the isolation wall portion 501 by the certain level difference S. As a result, the first circuit patterns 310P may be formed in concave circuit trenches 504 defined by the isolation wall portion 501, respectively. The first circuit patterns 310P may be disposed in the circuit trenches 504, and the top surface 502 of the isolation wall portion 501 may be exposed. The first circuit patterns 310P may be spaced apart from each other by a width of the isolation wall portion 501 in a horizontal direction. In particular, if the first conductive layers 300 is recessed so that the certain level difference S exists between the top surface 502 of the isolation wall portion 501 and the top surface of each of the first circuit patterns 310P, the first circuit patterns 310P may be more clearly separated from each other.

The isolation wall portion 501 may function as a barrier that improves an effect of separating the first circuit patterns 310P. Since the isolation wall portion 501 protrudes from the top surfaces of the first circuit patterns 310P, an effective distance (along a surface of the isolation wall portion 501) between the first circuit patterns 310P may increase. Thus, an ion migration phenomenon occurring between the first circuit patterns 310P may be suppressed to improve an electrical characteristic (e.g., a leakage current characteristic) between the first circuit patterns 310P.

While the first conductive layer (300 of FIG. 8) is recessed to form the first circuit patterns 310P, the second conductive layer (600 of FIG. 8) may also be recessed to provide a second conductive layer 611 having a reduced thickness. The second conductive layer 611 may be provided to have a thickness that is appropriate for formation of second circuit patterns in a subsequent process.

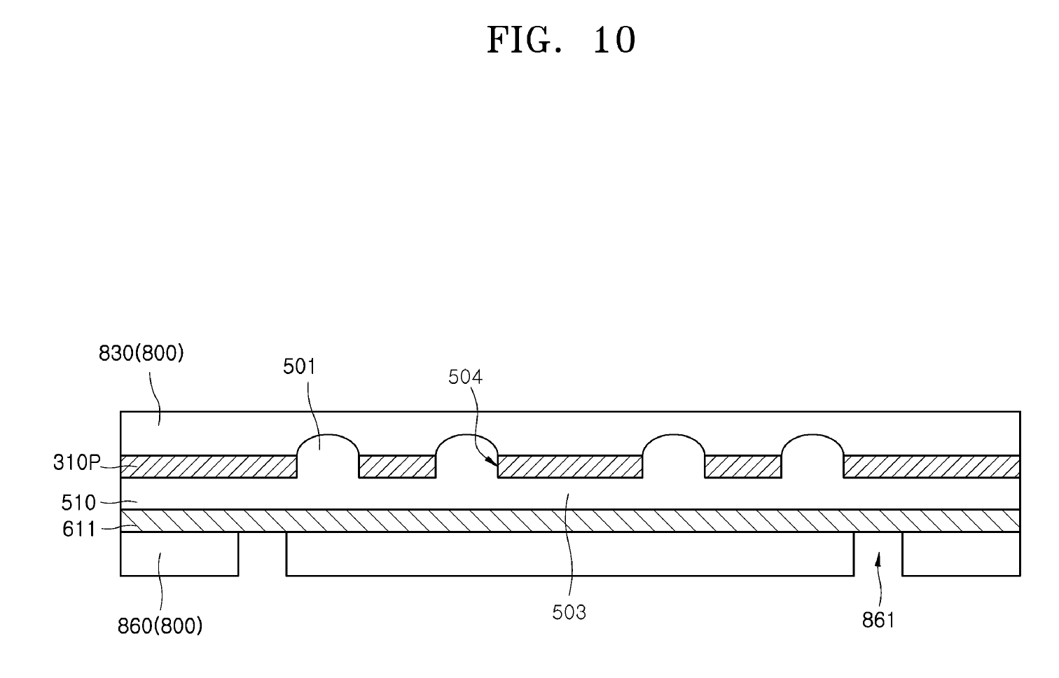

FIG. 10 illustrates a step of forming a second etch mask 800 exposing portions of the second conductive layer 611.

Referring to FIG. 10, a second etch mask 800 for patterning the second conductive layer 611 may be formed on the second conductive layer 611 and the first circuit patterns 310P. Specifically, the second etch mask 800 may be formed to include a second front side etch mask 830 covering the first circuit patterns 310P and a second back side etch mask 860 having third openings 861 that expose portions of the second conductive layer 611. The second front side etch mask 830 may be formed by attaching a dry film to the first circuit patterns 310P and the isolation wall portion 501 using a lamination process. The second back side etch mask 860 may be formed by attaching a dry film having the third openings 861 to the second conductive layer 611 using a lamination process.

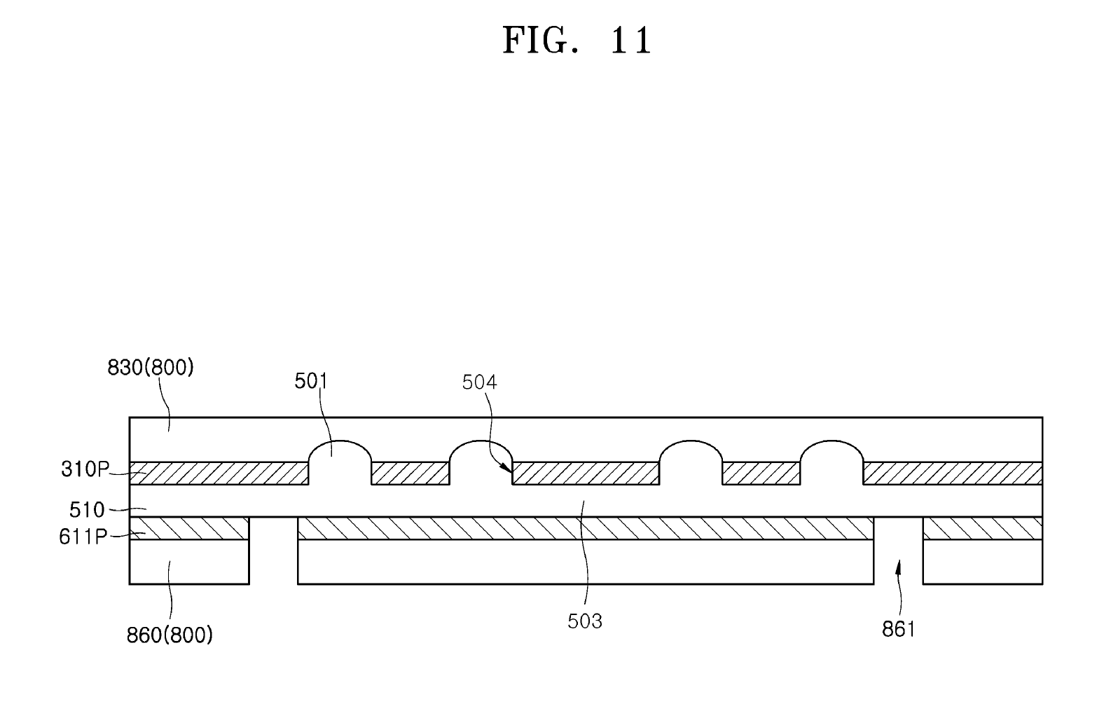

FIG. 11 illustrates a step of forming second circuit patterns 611P.

Referring to FIG. 11, portions of the second conductive layer 611 exposed by the third openings 861 of the second back side etch mask 860 may be etched and removed using an etch process. In such a case, the etch process for etching the exposed portions of the second conductive layer 611 may be performed until the first front side dielectric layer 510 is exposed. The etch process for etching the exposed portions of the second conductive layer 611 may be performed using a wet etch technique. After the second conductive layer 611 is etched, portions of the second conductive layer 611 may remain between the second back side etch mask 860 and the first front side dielectric layer 510 to act as the second circuit patterns 611P.

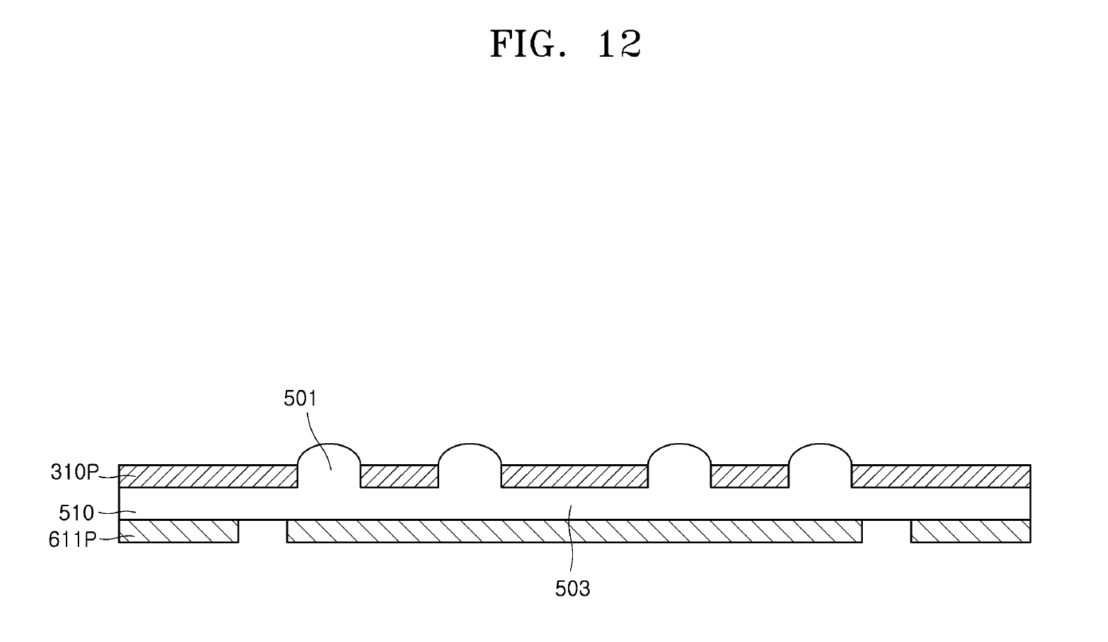

FIG. 12 illustrates a step of exposing the second circuit patterns 611P.

Referring to FIG. 12, after the second circuit patterns 611P are formed, the second etch mask 800 may be removed to expose the first and second circuit patterns 310P and 611P. As a result, the first circuit patterns 310P may be disposed on a surface of the first front side dielectric layer 510, and the second circuit patterns 611P may be disposed on another surface of the first front side dielectric layer 510 opposite to the first circuit patterns 310P.

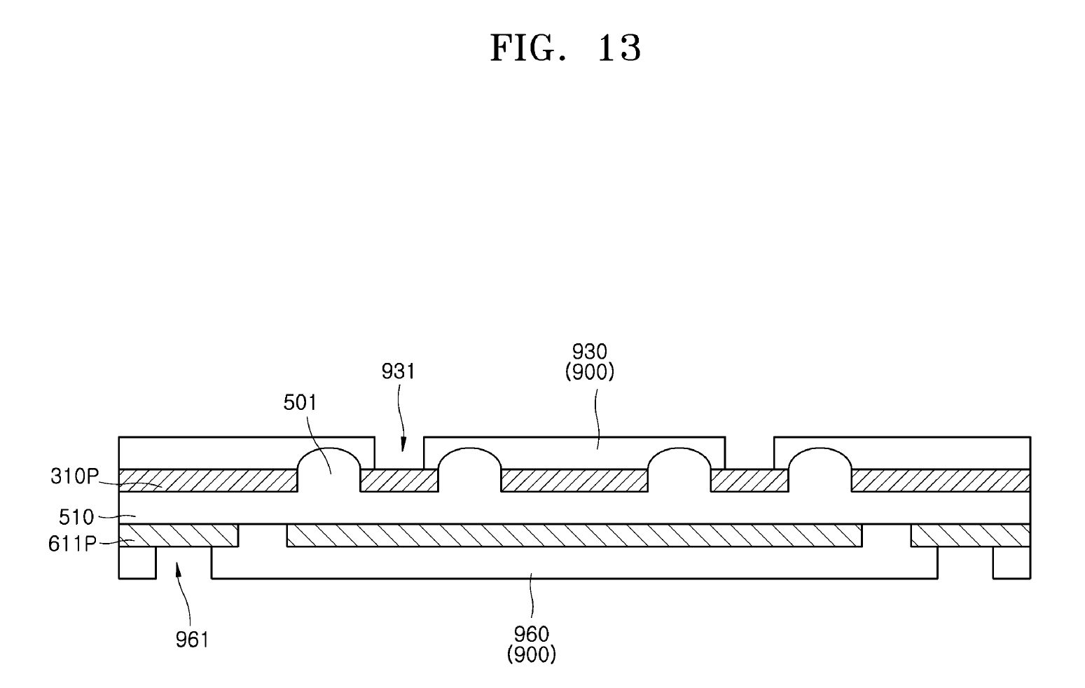

FIG. 13 illustrates a step of forming an outer dielectric layer 900.

Referring to FIG. 13, the outer dielectric layer 900 may be formed on the first and second circuit patterns 310P and 611P. The outer dielectric layer 900 may be formed to expose portions of the first circuit patterns 310P and portions of the second circuit patterns 611P. The outer dielectric layer 900 may be formed of a solder resist material using a print technique. The outer dielectric layer 900 may be formed to include a second dielectric layer 930 having fourth openings 931 that expose portions of the first circuit patterns 310P and a third dielectric layer 960 having fifth openings 961 that expose portions of the second circuit patterns 611P.

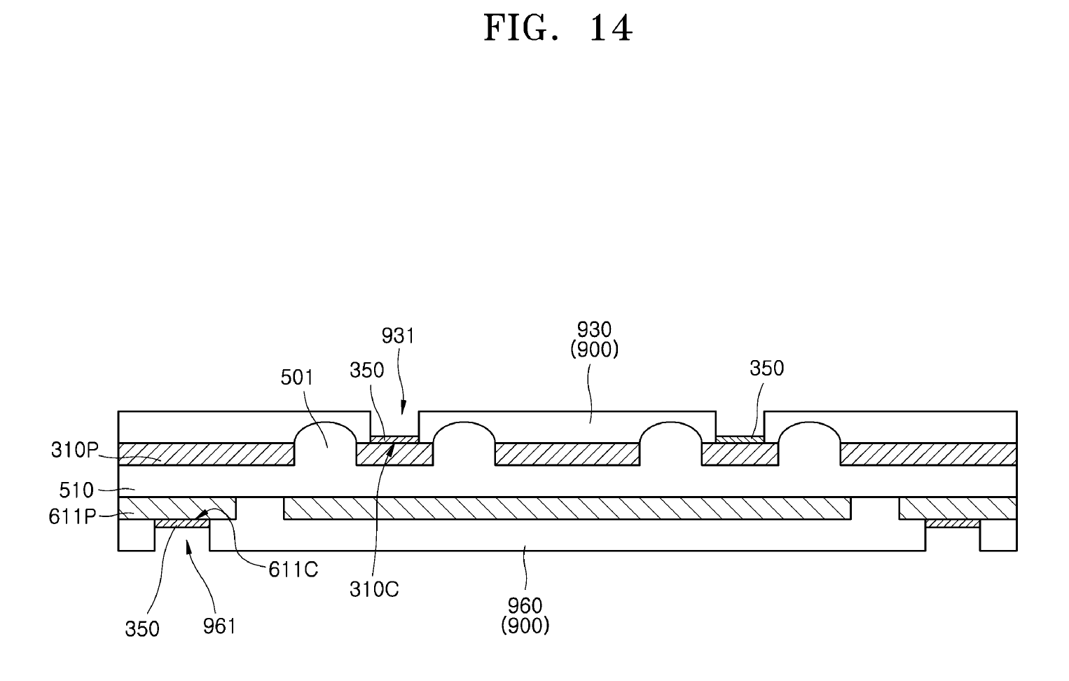

FIG. 14 illustrates a step of performing a final surface treatment process.

Referring to FIG. 14, an oxidation resistant layer 350 may be formed on portions of the first and second circuit patterns 310P and 611P exposed by the fourth and fifth openings 931 and 961 of the outer dielectric layer 900. After the oxidation resistant layer 350 is formed, fabrication of a package substrate may be completed. The oxidation resistant layer 350 may be formed to include a metal layer, for example, a gold (Au) layer. The first circuit patterns 310P covered with the oxidation resistant layer 350 may act as first connectors 310C, and the second circuit patterns 611P covered with the oxidation resistant layer 350 may act as second connectors 611C. The first and second connectors 310C and 611C may constitute an electrical interconnection structure that electrically connect the package substrate to external electronic components, external electronic devices or external semiconductor devices.

An additional dielectric layer and additional circuit patterns may be formed on the first circuit patterns 311P or the second circuit patterns 611P to provide a multi-layered package substrate.

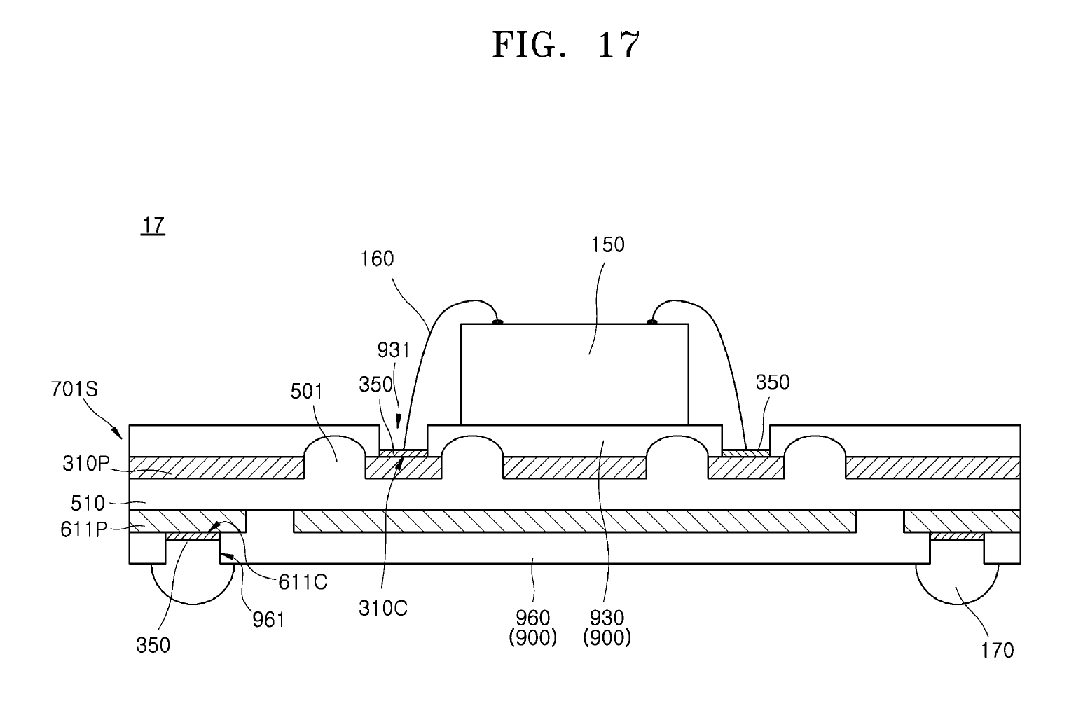

FIG. 17 is a cross-sectional view illustrating a semiconductor package 17 including a package substrate 701S according to an embodiment.

Referring to FIG. 17, the semiconductor package 17 may include the package substrate 701S and a semiconductor device 150 mounted on the package substrate 701S. The semiconductor device 150 may be electrically connected to the package substrate 701S through bonding wires 160.

The package substrate 701S may have the same configuration as the package substrate formed by the method described with reference to FIGS. 1 to 16. Accordingly, the package substrate 701S may include the isolation wall portion 501 protruding from a surface of the first front side dielectric layer 510. Another surface of the first front side dielectric layer 510 opposite to the isolation wall portion 501 may be substantially flat.

The first circuit patterns 310P may be located in concave circuit trenches defined by the isolation wall portion 501. As described with reference to FIG. 9, the top surfaces of the first circuit patterns 310P may be located at a level which is lower than the top surface (502 of FIG. 9) of the isolation wall portion 501. Thus, the first circuit patterns 310P may be disposed to have an embedded pattern shape. That is, the first circuit patterns 310P may be embedded in or covered with the second dielectric layer 930 which is disposed on a surface of the first front side dielectric layer 510. Accordingly, the package substrate 701S may be a substrate including embedded patterns.

The isolation wall portion 501 may be disposed between the first circuit patterns 310P and may protrude from the top surfaces of the first circuit patterns 310P. Thus, the isolation wall portion 501 may function as a barrier that improves an electrical insulation characteristic between the first circuit patterns 310P or suppresses a metal migration phenomenon between the first circuit patterns 310P. Since an electrical and physical isolation characteristic of the first circuit patterns 310P is improved due to the presence of the isolation wall portion 501, a pitch size of the first circuit patterns 310P may be reduced.

The second circuit patterns 611P may be formed on a surface of the first front side dielectric layer 510 opposite to the isolation wall portion 501 to have a mesa shape or a protrusion shape. While each of the second circuit patterns 611P is formed on a surface of the first front side dielectric layer 510 to have a mesa shape, the first circuit patterns 310P may be formed in the circuit trenches (504 of FIG. 9) defined by the isolation wall portion 501 by depositing a conductive layer and by etching-back the conductive layer until the first front side dielectric layer 510 is exposed. Thus, the first circuit patterns 310P may be disposed to have a fine pitch size which is less than a pitch size of the second circuit patterns 611P. That is, since the first circuit patterns 310P may be separated from each other by the first front side dielectric layer 510 without using a general patterning process, the first circuit patterns 310P may have a fine width which is less than a width of the second circuit patterns 611P.

The second dielectric layer 930 having the fourth openings 931 exposing portions of the first circuit patterns 310P may be disposed on a surface of the first front side dielectric layer 510, and the third dielectric layer 960 having the fifth openings 961 exposing portions of the second circuit patterns 611P may be disposed on another surface of the first front side dielectric layer 510 opposite to the second dielectric layer 930. The oxidation resistant layer 350 may be disposed on portions of the first and second circuit patterns 310P and 611P exposed by the openings 931 and 961 of the outer dielectric layer 900 including the second and third dielectric layers 930 and 960. The first circuit patterns 310P covered with the oxidation resistant layer 350 may act as the first connectors 310C, and the second circuit patterns 611P covered with the oxidation resistant layer 350 may act as the second connectors 611C. The bonding wires 160 may be bonded to the first connectors 310C to electrically connect the first connectors 310C (i.e., the package substrate 701S) to the semiconductor device 150. External connection members 170 may be attached to the second connectors 611C to electrically connect the semiconductor package 17 to an external electronic device, an external semiconductor device, an external substrate or an external module. A protection layer (not illustrated) may be disposed to cover the semiconductor device 150. The protection layer may include an epoxy molding compound (EMC) material.

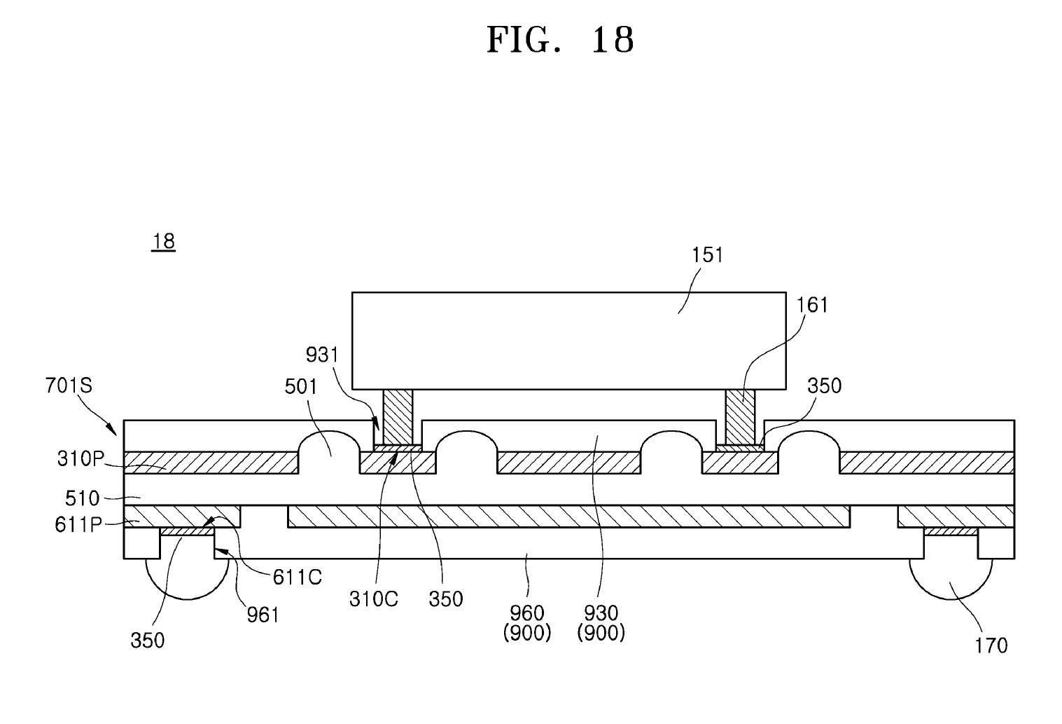

FIG. 18 is a cross-sectional view illustrating a semiconductor package 18 including the package substrate 701S according to an embodiment.

Referring to FIG. 18, the semiconductor package 18 may include the package substrate 701S and a semiconductor device 151 mounted on the package substrate 701S. The semiconductor device 151 may be electrically connected to the package substrate 701S through connection bumps 161.

The package substrate 701S may have the same configuration as the package substrate formed by the method described with reference to FIGS. 1 to 16. The package substrate 701S may include the first circuit patterns 310P and the second circuit patterns 611P disposed on the first front side dielectric layer 510, as described with reference to FIG. 17. The connection bumps 161 may be combined with the first connectors 310C to electrically connect the first connectors 310C (i.e., the package substrate 701S) to the semiconductor device 151. The external connection members 170 may be attached to the second connectors 611C to electrically connect the semiconductor package 18 to, for example but not limited to, an external electronic device, an external semiconductor device, an external substrate or an external module. A protection layer (not illustrated) may be disposed to cover the semiconductor device 151. The protection layer may include an epoxy molding compound (EMC) material.

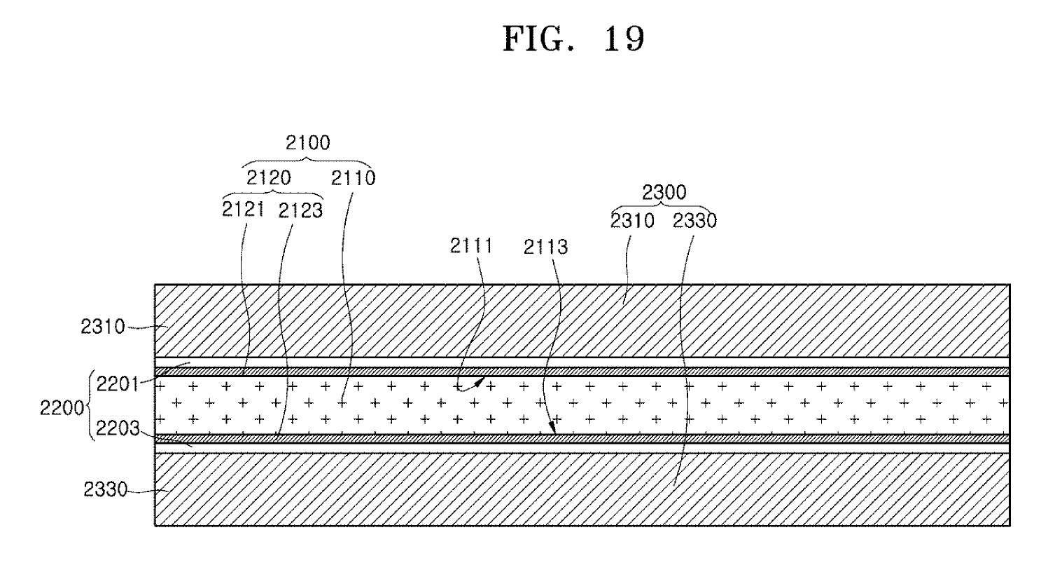

FIGS. 19 to 29 are cross-sectional views illustrating examples of representations of a method of fabricating a package substrate according to an embodiment. FIGS. 19 to 29 illustrates a method of fabricating a package substrate having circuit patterns located at a single level.

FIG. 19 illustrates a step of forming a conductive layer 2300 on a carrier layer 2100.

Referring to FIG. 19, a structure that the conductive layer 2300 is stacked on the carrier layer 2100 may be provided. The carrier layer 2100 may function as a support substrate or a subsidiary substrate for supporting and handling the conductive layer 2300 during subsequent processes. The conductive layer 2300 may be formed to include a front side conductive layer 2310 disposed on a front side surface of the carrier layer 2100 and a back side conductive layer 2330 disposed on a back side surface of the carrier layer 2100.

The conductive layer 2300 may be formed to include copper or copper alloy. The conductive layer 2300 may be formed by attaching a conductive foil to one surface or two opposite surfaces of the carrier layer 2100. The carrier layer 2100 may include a copper clad laminate (CCL) structure. The CCL structure may have a structure that a couple of conductive clad layers 2120 are respectively laminated on two opposite surfaces 2111 and 2113 of an insulation core layer 2110. The insulation core layer 2110 may include a resin material or a composite material formed of a fabric material containing resin. The fabric material may include glass fiber or glass fabric. The conductive clad layers 2120 may be formed to include a first conductive clad layer 2121 laminated on a first surface 2111 of the insulation core layer 2110 and a second conductive clad layer 2123 laminated on a second surface 2113 of the insulation core layer 2110 opposite to the first conductive clad layer 2121. The conductive clad layers 2120 may be formed to include copper or copper alloy. In general, the CCL structure may be used as a main substrate in fabrication of a package substrate. However, according to the embodiment, the CCL structure may be used as a subsidiary substrate or the carrier layer 2100 for supporting the conductive layer 2300. Thus, another support substrate having a structure other than the CCL structure may also be used as the carrier layer 2100.

The conductive layer 2300 may be formed by attaching a conductive foil to the carrier layer 2100. For example, the conductive layer 2300 may be formed by laminating a copper foil or a copper alloy foil on the carrier layer 2100 having the CCL structure. An adhesive layer 2200 may be formed between the conductive layer 2300 (i.e., the copper foil or the copper alloy foil) and the carrier layer 2100 (i.e., the CCL structure) to laminate the copper foil or the copper alloy foil on the CCL structure. The adhesive layer 2200 may be formed to a thickness of about a few angstroms. The adhesive layer 2200 may include a first adhesive layer 2201 formed on the first conductive clad layer 2121 and a second adhesive layer 2203 formed on the second conductive clad layer 2123. In such a case, the front side conductive layer 2310 may be attached to the carrier layer 2100 using the first adhesive layer 2201, and the back side conductive layer 2330 may be attached to the carrier layer 2100 using the second adhesive layer 2203.

The conductive layer 2300 may be formed to provide circuit patterns of the package substrate. The conductive layer 300 may be formed to have a thickness which is greater than a thickness of the circuit patterns that are formed in a subsequent process. That is, the conductive layer 2300 may be etched back in a subsequent process to form the circuit patterns separated from each other. As a result, a thickness of the circuit patterns may be less than a thickness of the conductive layer 2300.

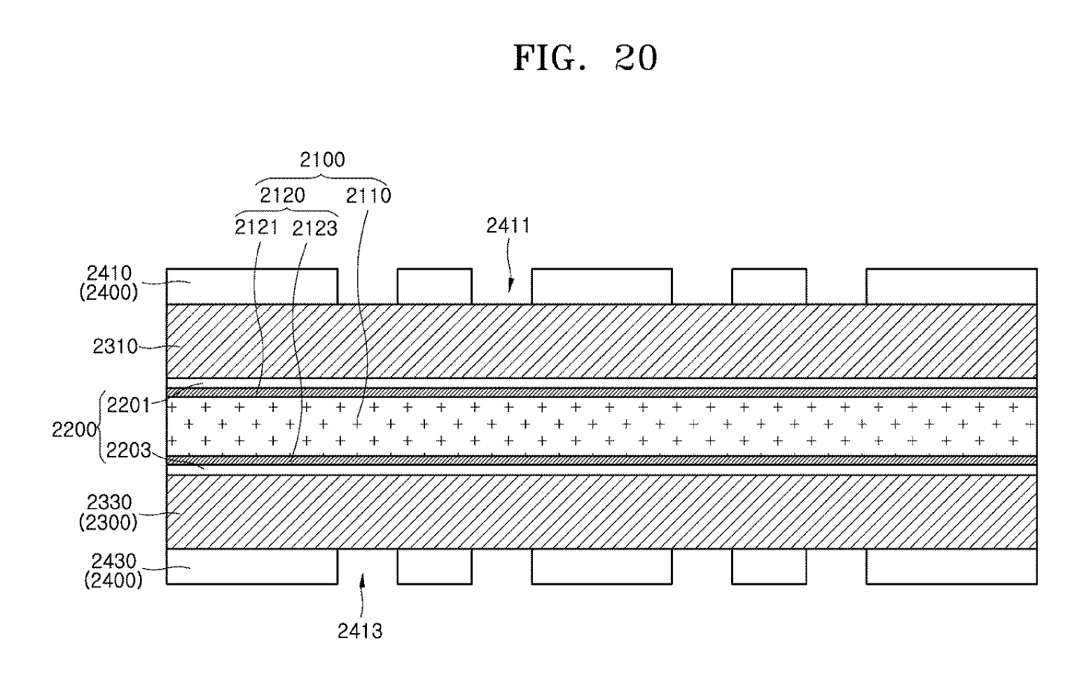

FIG. 20 illustrates a step of forming a first etch mask 2400 on the conductive layer 2300.

Referring to FIG. 20, the first etch mask 2400 may be formed to expose portions of the conductive layer 2300. The first etch mask 2400 may be formed by laminating a dry film on the conductive layer 2300 to expose portions of the conductive layer 2300. The first etch mask 400 may be formed to include a first front side etch mask 2410 having first openings 2411 that expose portions of the first front side conductive layer 2310 and a first back side etch mask 2430 having second openings 2413 that expose portions of the first back side conductive layer 2330.

The first openings 2411 may be located to vertically overlap with the second openings 2413, respectively. Accordingly, the first front side etch mask 2410 may be formed to have the same shape as the first back side etch mask 2430. In contrast, the first front side etch mask 2410 may be formed to have a different shape from the first back side etch mask 2430. In such a case, circuit patterns which are formed on the first conductive clad layer 2121 in a subsequent process may have a different shape from circuit patterns which are formed on the second conductive clad layer 2123 in a subsequent process.

The first etch mask 2400 may be formed to have the same pattern image as the circuit patterns which are realized in a subsequent process. Thus, the first and second openings 2411 and 2413 may be formed to exhibit a reverse image of the circuit patterns which are realized in a subsequent process. That is, the first and second openings 2411 and 2413 may be formed to have the same planar shape as a region between the circuit patterns.

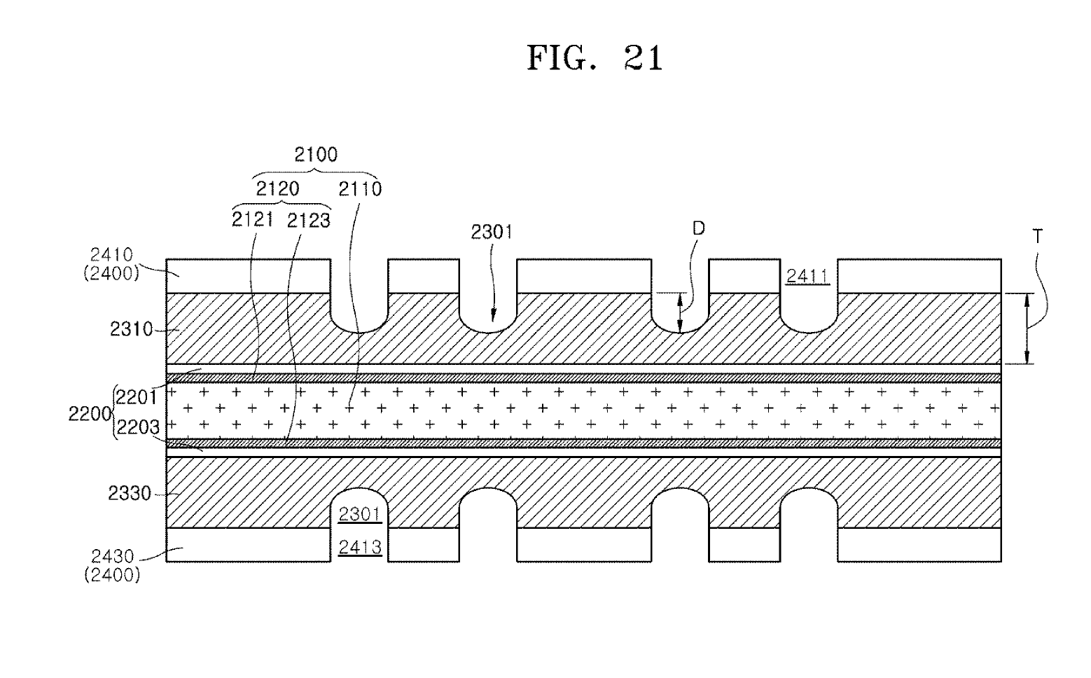

FIG. 21 illustrates a step of forming an isolation trench 2301 in the conductive layer 2300.

Referring to FIG. 21, the conductive layer 2300 exposed by the first and second openings 2411 and 2413 of the first etch mask 2400 may be etched to form the isolation trench 2301. As described above, the first and second openings 2411 and 2413 may have the same planar shape as the region between the circuit patterns. Thus, the isolation trench 2301 may be formed in order to separate the circuit patterns from each other.

The isolation trench 2301 may be formed to have a depth D which is less than a thickness T of the conductive layer 2300. That is, the isolation trench 2301 may be formed not to penetrate the conductive layer 2300 so that a portion of the conductive layer 2300 remains below a bottom surface of the isolation trench 2301. In order to form the isolation trench 2301, the conductive layer 2300 may be etched using a partial etch process, for example, a half etch process not to expose the first and second conductive clad layers 2121 and 2123. The etch process for forming the isolation trench 2301 may be performed using a wet etch process for removing a copper material. In such a case, the depth D of the isolation trench 2301 may be controlled by adjusting an etch time of the wet etch process or a concentration of an etchant used in the wet etch process.

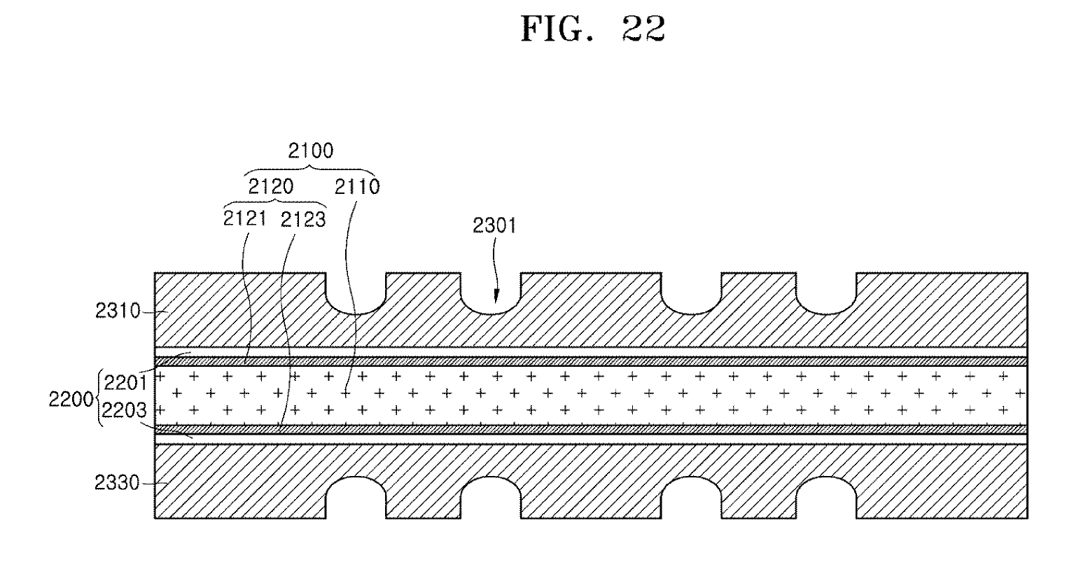

FIG. 22 illustrates a step of exposing the conductive layer 2300.

Referring to FIG. 22, after the isolation trench 2301 is formed in the conductive layer 2300 to have a dented shape, the first etch mask (2400 of FIG. 21) may be removed. That is, the dry film used as the first etch mask 2400 may be striped to expose an entire surface of the conductive layer 2300.

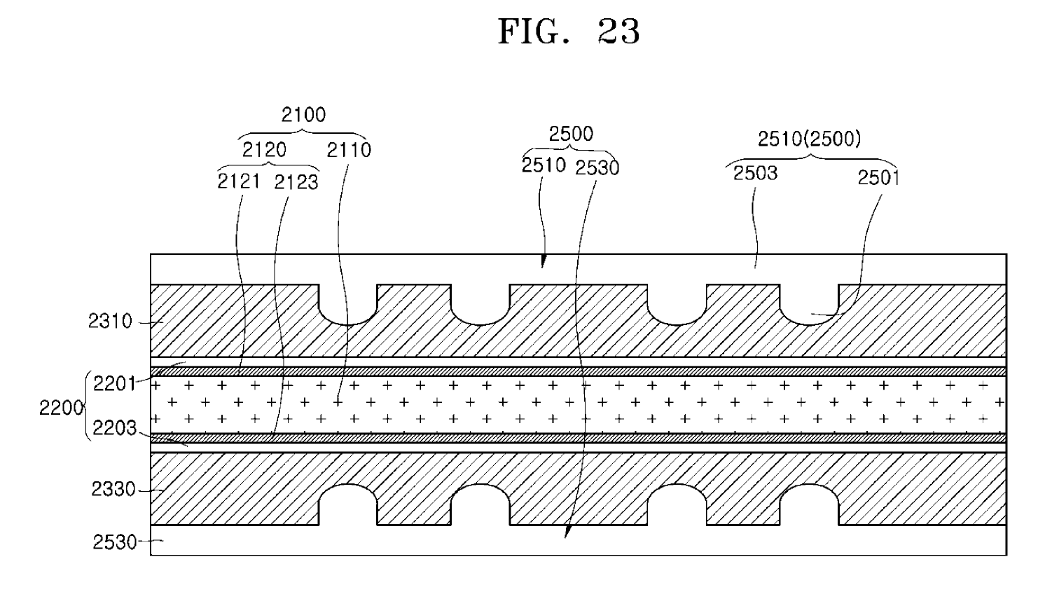

FIG. 23 illustrates a step of forming a first dielectric layer 2500.

Referring to FIG. 23, the first dielectric layer 2500 may be formed on the conductive layer 2300 to fill the isolation trench 2301. The first dielectric layer 2500 may be formed to provide a body of an insulation portion of the package substrate. The first dielectric layer 2500 may include an isolation wall portion 2501 filling the isolation trench 2301. The first dielectric layer 2500 may also include a body portion 2503 that extends from the isolation wall portion 2501 to cover a top surface of the conductive layer 2300. The isolation wall portion 2501 may have a protrusion shape that substantially protrudes from a surface of the body portion 2503. The conductive layer 2300 may be located between the adjacent isolation wall portions 2501.

The first dielectric layer 2500 may be formed by stacking a prepreg layer on the conductive layer 2300 with a lamination process. The prepreg layer may include a resin material such as an epoxy material or may include a resin matrix layer containing a reinforced fiber material. The first dielectric layer 2500 may include a first front side dielectric layer 2510 formed on the front side conductive layer 2310 and a first back side dielectric layer 2530 formed on the back side conductive layer 2330. The first front side dielectric layer 2510 and the first back side dielectric layer 2530 may be simultaneously formed on two opposite surfaces of the carrier layer 2100, respectively.

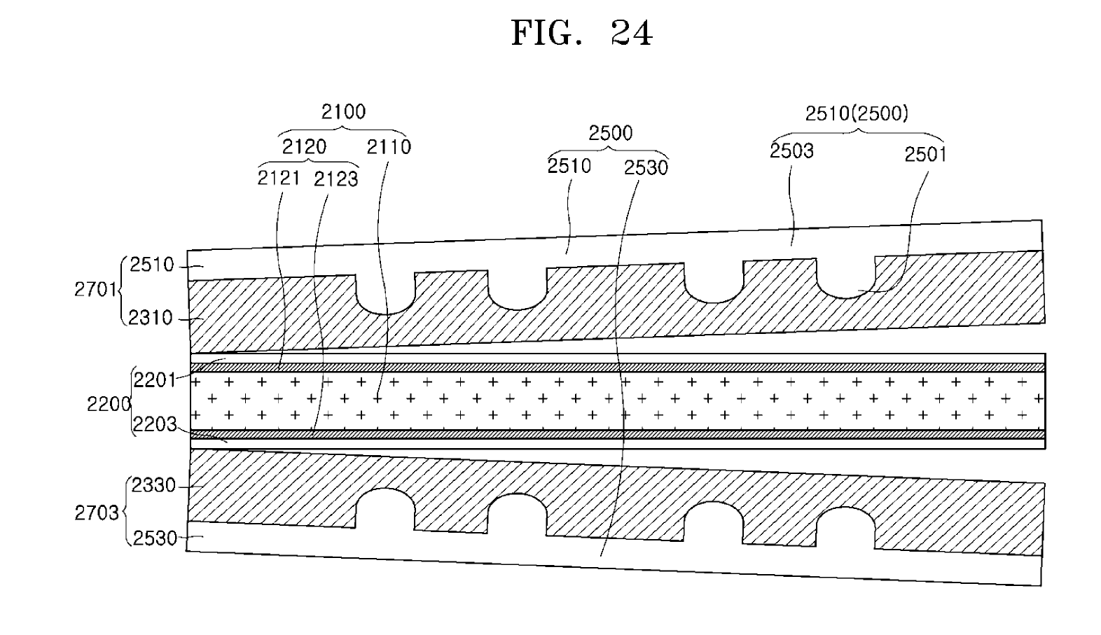

FIG. 24 illustrates a step of separating the first and second stack structures 2701 and 2703 from the carrier layer 2100.

Referring to FIG. 24, the front side conductive layer 2310 and the first front side dielectric layer 2510 may constitute the first stack structure 2701, and the back side conductive layer 2330 and the first back side dielectric layer 2530 may constitute the second stack structure 2703. The first and second stack structures 2701 and 2703 may be mirror symmetric with respect to the carrier layer 2100 disposed between the first and second stack structures 2701 and 2703.

The first and second stack structures 2701 and 2703 may be peeled from one edge of the carrier layer 2100 and may be completely separated from the carrier layer 2100. Each of the first and second stack structures 2701 and 2703 separated from the carrier layer 2100 may be used as a panel for providing a package substrate. Because the first and second stack structures 2701 and 2703 have the same configuration, each of the first and second stack structures 2701 and 2703 may be treated by substantially the same processes as described hereinafter.

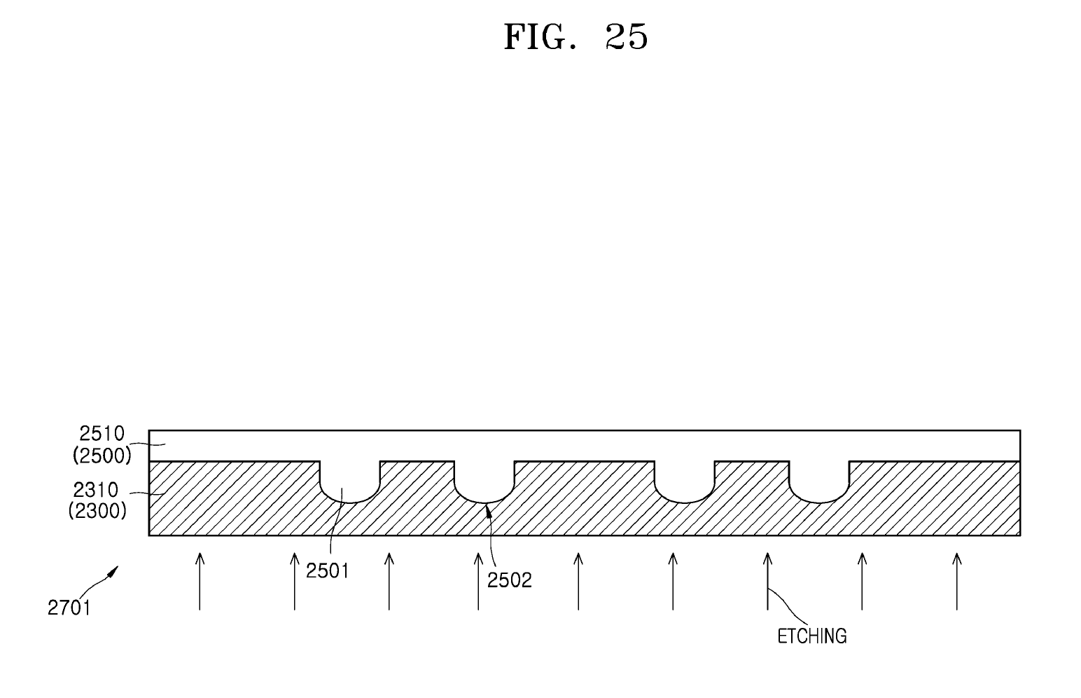

FIG. 25 illustrates a step of recessing the conductive layer 2300.

Referring to FIG. 25, the conductive layer 2300 may be recessed by a blanket etch-back process to reduce a thickness of the conductive layer 2300. The blanket etch-back process may be performed using a wet etch process. The blanket etch-back process for recessing the conductive layer 2300 may be performed using a half etch process to partially remove the conductive layer 2300. A thickness of the etched conductive layer 2300 may be controlled by adjusting an etch time of the blanket etch-back process or a concentration of an etchant used in the blanket etch-back process. That is, a thickness of the remaining conductive layer 2300 may be appropriately controlled by adjusting an etch time of the blanket etch-back process or a concentration of an etchant used in the blanket etch-back process.

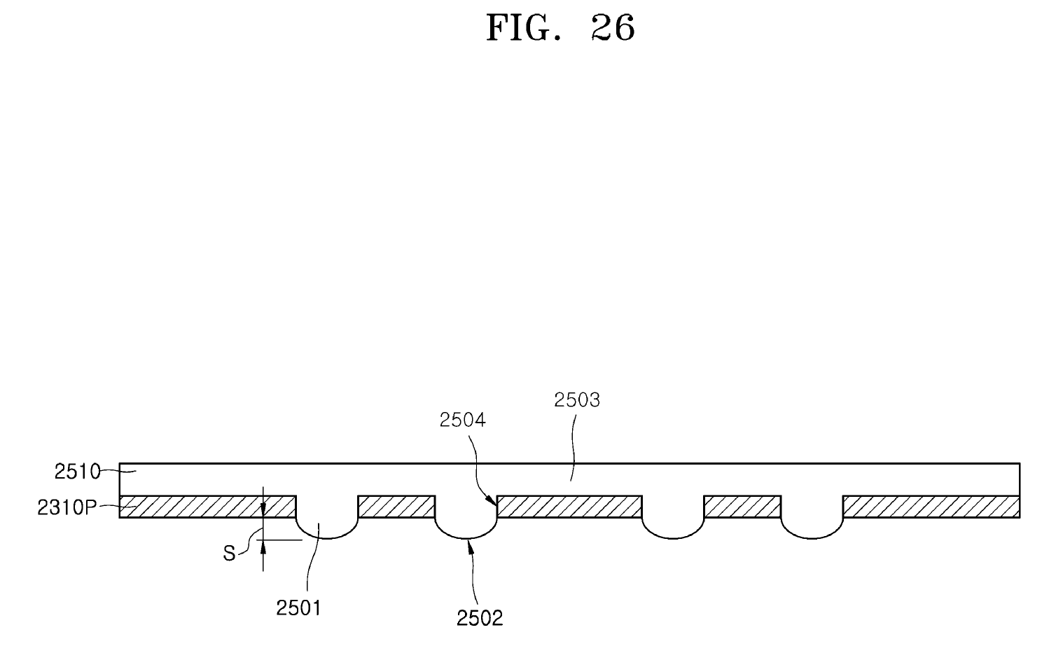

FIG. 26 illustrates a step of forming circuit patterns 2310P.

Referring to FIGS. 25 and 26, the blanket etch-back process for recessing the conductive layer 2300 may be performed until a top surface 2502 of an upper portion of the isolation wall portion 2501 is exposed. Even after the top surface 2502 of the isolation wall portion 2501 is exposed, the conductive layer 2300 may be additionally recessed to form the plurality of circuit patterns 2310P which are comprised of the conductive layer 2300 and separated from each other. That is, the circuit patterns 2310P may correspond to remaining portions of the conductive layer 2300 which are separated from each other by the isolation wall portion 2501.

The blanket etch-back process for recessing the conductive layer 2300 may include an over-etch step that is performed so that a certain level difference S exists between the top surface 2502 of the isolation wall portion 2501 and a top surface of each of the circuit patterns 2310P. That is, the top surfaces of the circuit patterns 2310P may be located at a level which is lower than the top surface 2502 of the isolation wall portion 2501 by the certain level difference S. As a result, the circuit patterns 2310P may be formed in concave circuit trenches 2504 defined by the isolation wall portion 2501, respectively. After the conductive layer 2300 is over-etched, the circuit patterns 2310P may be disposed in the circuit trenches 2504 and upper portions of sidewalls of the isolation wall portion 2501 may be exposed. The circuit patterns 2310P may be spaced apart from each other by a width of the isolation wall portion 2501 in a horizontal direction. In particular, if the conductive layer 2300 is recessed so that the certain level difference S exists between the top surface 2502 of the isolation wall portion 2501 and the top surface of each of the circuit patterns 2310P, the circuit patterns 2310P may be more clearly separated from each other.

The isolation wall portion 2501 may function as a barrier that improves an effect of separating the circuit patterns 2310P. Since the isolation wall portion 2501 protrudes from the top surfaces of the circuit patterns 2310P, an effective distance (along a surface of the isolation wall portion 2501) between the circuit patterns 2310P may increase. Thus, an ion migration phenomenon occurring between the first circuit patterns 2310P may be suppressed to improve an electrical characteristic (e.g., a leakage current characteristic) between the circuit patterns 2310P.

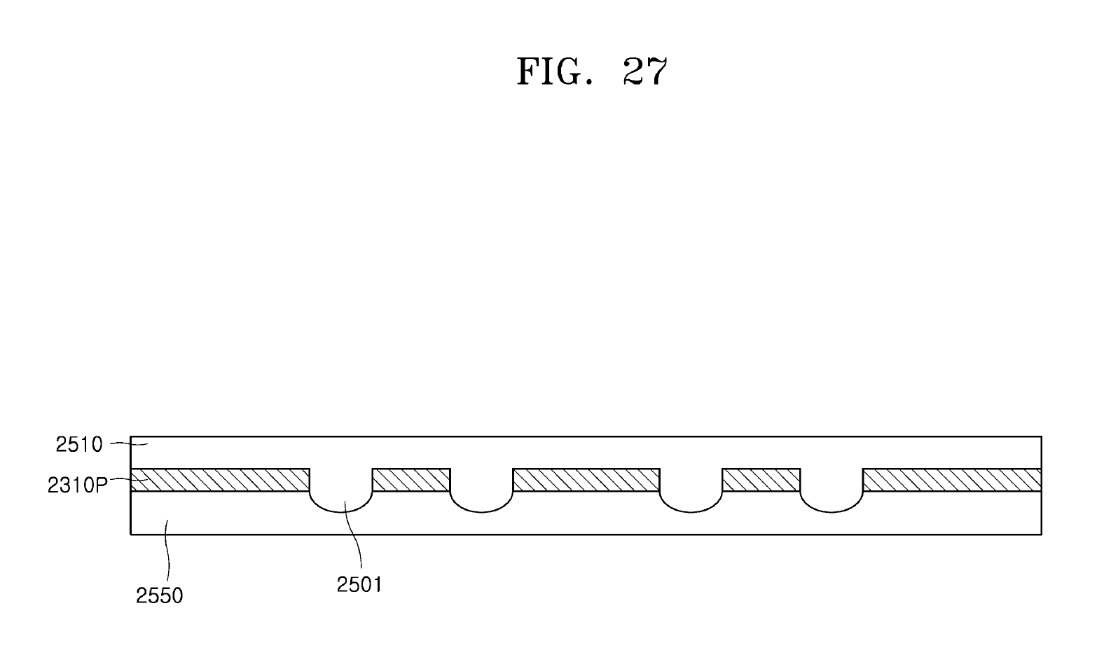

FIG. 27 illustrates a step of forming a second dielectric layer 2550 covering the circuit patterns 2310P.

Referring to FIG. 27, the second dielectric layer 2550 may be formed on the circuit patterns 2310P and the isolation wall portion 2501. The second dielectric layer 2550 may be laminated on the isolation wall portion 2501 to cover the circuit patterns 2310P. As a result, the circuit patterns 2310P may be embedded in a dielectric layer comprised of the first front side dielectric layer 2510 and the second dielectric layer 2550. The second dielectric layer 2550 may be formed to include an organic material such as an epoxy resin material. In some embodiments, the second dielectric layer 2550 may be formed to include a solder resist material.

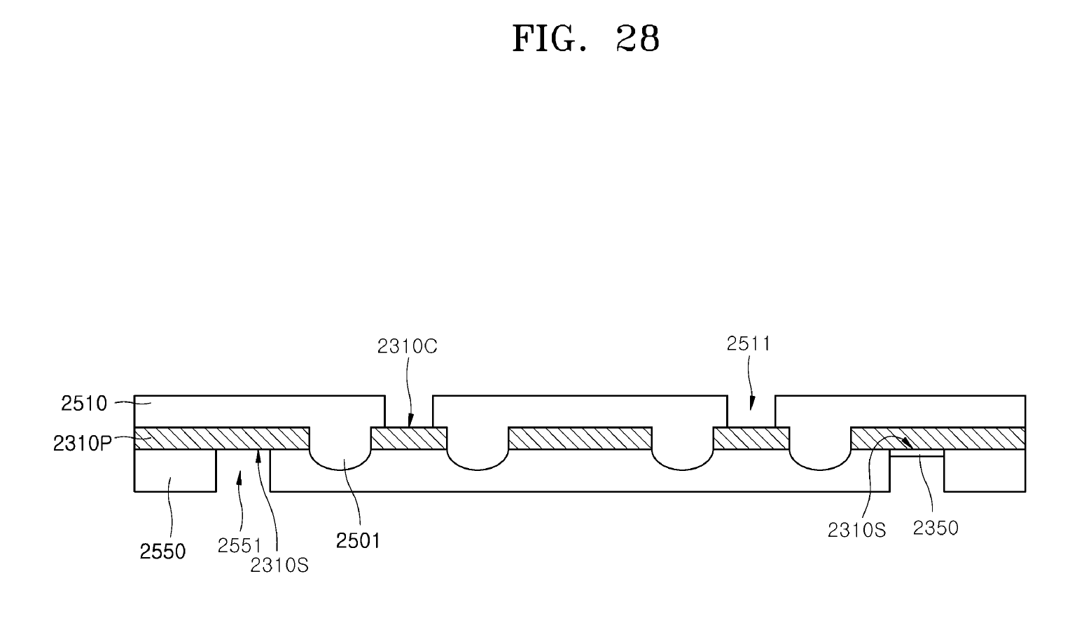

FIG. 28 illustrates a step of exposing the circuit patterns 2310P acting as first connectors 2310C and second connectors 2310S.

Referring to FIG. 28, the first front side dielectric layer 2510 may be patterned to form third openings 2511 that expose portions of the circuit patterns 2310P. The portions of the circuit patterns 2310P exposed by the third openings 2511 may act as the first connectors 2310C which are electrically connected to an external device. The second dielectric layer 2550 may be patterned to form fourth openings 2551 that expose other portions of the circuit patterns 2310P. The other portions of the circuit patterns 2310P exposed by the fourth openings 2551 may act as the second connectors 2310S which are electrically connected to an external device.

The first connectors 2310C may be opened toward a first direction, and the second connectors 2310C may be opened toward a second direction opposite to the first direction. For example, the third openings 2511 exposing the first connectors 2310C may be located on front side surfaces of the circuit patterns 2310P opposite to the second dielectric layer 2550, and the fourth openings 2551 exposing the second connectors 2310S may be located on back side surfaces of the circuit patterns 2310P opposite to the first front side dielectric layer 2510. The first connectors 2310C may be disposed not to vertically overlap with the second connectors 2310S, as illustrated in FIG. 28. Alternatively, although not shown in the drawings, the first connectors 2310C may be disposed to vertically overlap with the second connectors 2310S, respectively.

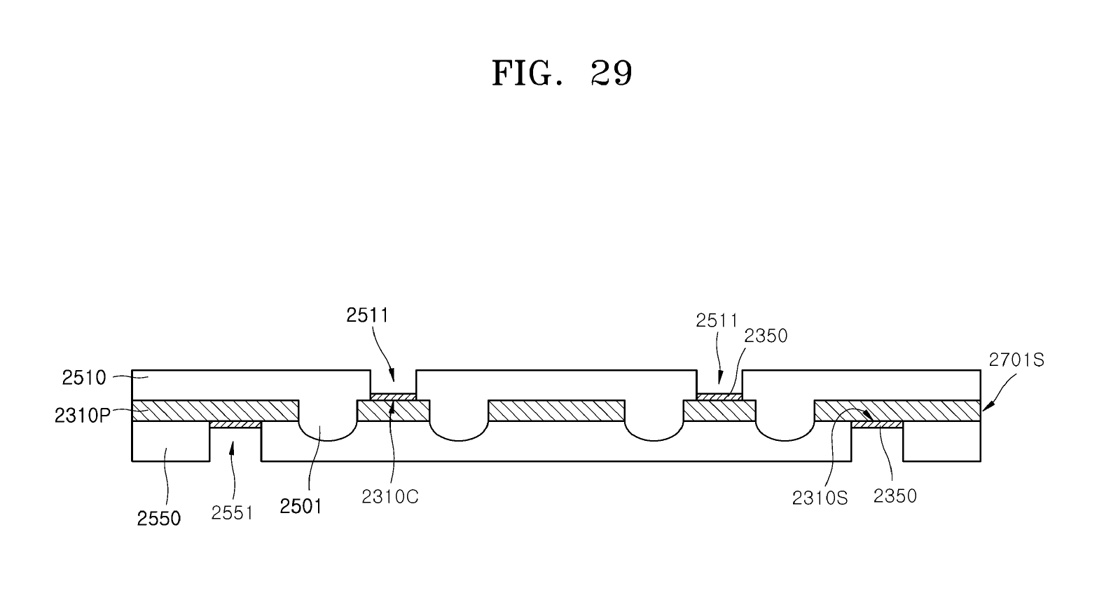

FIG. 29 illustrates a step of performing a final surface treatment process.

Referring to FIG. 29, an oxidation resistant layer 2350 may be formed on the exposed portions of the circuit patterns 2310P, that is, on the exposed surfaces of the first and second connectors 2310C and 2310S. The circuit patterns 2310P, the first front side dielectric layer 2510, the second dielectric layer 2550 and the oxidation resistant layer 2350 may constitute a package substrate. The oxidation resistant layer 2350 may be formed to include a metal layer, for example, a gold (Au) layer. The first and second connectors 2310C and 2310S may constitute an electrical interconnection structure that electrically connect the package substrate to external electronic components, external electronic devices or external semiconductor devices. The first and second connectors 2310C and 2310S may be located at the same level. Accordingly, the package substrate may be formed to include the circuit patterns 2310P located at a single level.

An additional dielectric layer and additional circuit patterns may be formed on the first front side dielectric layer 2510 or the second dielectric layer 2550 to provide a multi-layered package substrate.

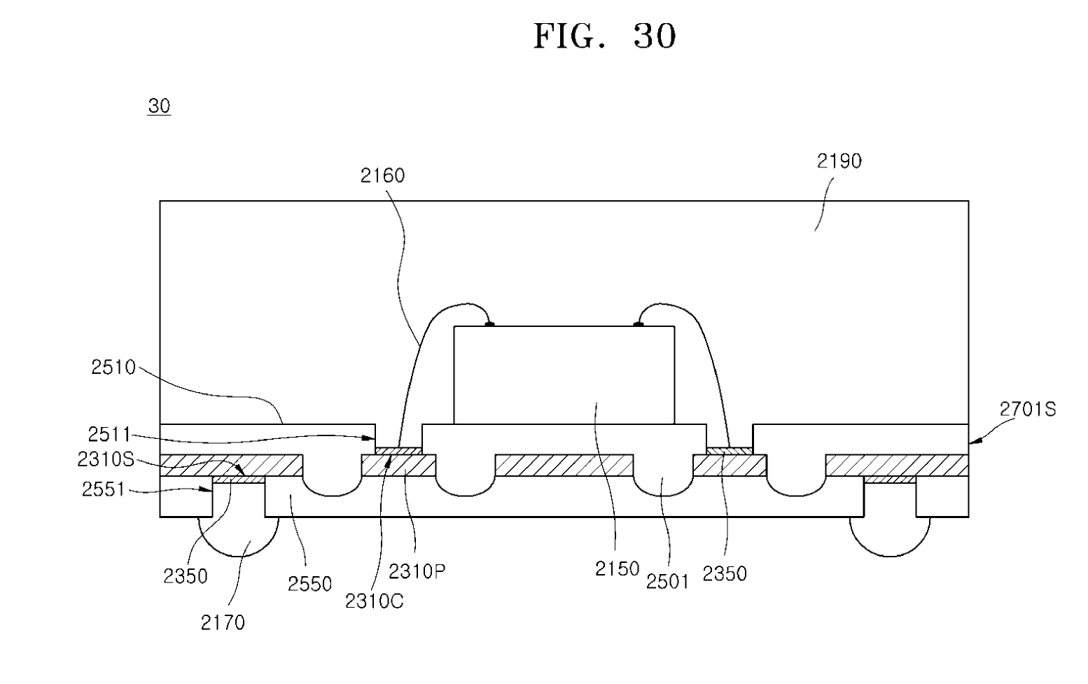

FIG. 30 is a cross-sectional view illustrating a semiconductor package 30 including a package substrate 2701S according to an embodiment.

Referring to FIG. 30, the semiconductor package 30 may include the package substrate 2701S and a semiconductor device 2150 mounted on the package substrate 2701S. The semiconductor device 2150 may be electrically connected to the package substrate 2701S through bonding wires 2160.

The package substrate 2701S may have the same configuration as the package substrate formed by the method described with reference to FIGS. 19 to 29. Accordingly, the package substrate 2701S may include the isolation wall portion 2501 protruding from a surface of the first front side dielectric layer 2510. Another surface of the first front side dielectric layer 2510 opposite to the isolation wall portion 2501 may be substantially flat.

The circuit patterns 2310P may be disposed in circuit trenches defined by the isolation wall portion 2501. As described with reference to FIG. 26, the top surfaces of the circuit patterns 2310P may be located at a level which is lower than the top surface (2502 of FIG. 26) of the isolation wall portion 2501. Thus, the circuit patterns 2310P may be disposed to have an embedded pattern shape. That is, the circuit patterns 2310P may be embedded in or covered with a dielectric layer including the first front side dielectric layer 2510 and the second dielectric layer 2550. Accordingly, the package substrate 2701S may be a substrate including embedded patterns.

The isolation wall portion 2501 may be disposed between the circuit patterns 2310P and may protrude from the top surfaces of the circuit patterns 2310P. Thus, the isolation wall portion 2501 may function as a barrier that improves an electrical insulation characteristic between the circuit patterns 2310P or suppresses a metal migration phenomenon between the circuit patterns 2310P. Since an electrical and physical isolation characteristic of the circuit patterns 2310P is improved due to the presence of the isolation wall portion 2501, a pitch size of the circuit patterns 2310P may be reduced.

The package substrate 2701S may further include the second dielectric layer 2550 covering the circuit patterns 2310P. The second dielectric layer 2550 may extend to cover a top surface and upper sidewalls of the isolation wall portion 2501 as well as top surfaces of the circuit patterns 2310P. Accordingly, the package substrate 2701S may be realized to include the circuit patterns 2310P that are located at the same level and embedded in a dielectric layer comprised of the first front side dielectric layer 2510 and the second dielectric layer 2550.

The first front side dielectric layer 2510 may include the third openings 2511 that expose some portions of the front side surfaces of the circuit patterns 2310P, and the portions of the circuit patterns 2310P exposed by the third openings 2511 may act as the first connectors 2310C. The exposed surfaces of the first connectors 2310C may be covered with the oxidation resistant layer 2350. The second dielectric layer 2550 may include the fourth openings 2551 that expose some portions of the back side surfaces of the circuit patterns 2310P, and the portions of the circuit patterns 2310P exposed by the fourth openings 2551 may act as the second connectors 2310S. The exposed surfaces of the second connectors 2310S may also be covered with the oxidation resistant layer 2350.

The bonding wires 2160 may be bonded to the first connectors 2310C to electrically connect the first connectors 2310C (i.e., the package substrate 2701S) to the semiconductor device 2150. External connection members 2170 may be attached to the second connectors 2310S to electrically connect the semiconductor package 30 to, for example but not limited to, an external electronic device, an external semiconductor device, an external substrate or an external module. The external connection members 2170 may be solder balls. A protection layer 2190 may be disposed to cover the semiconductor device 2150. The protection layer 2190 may include an epoxy molding compound (EMC) material.

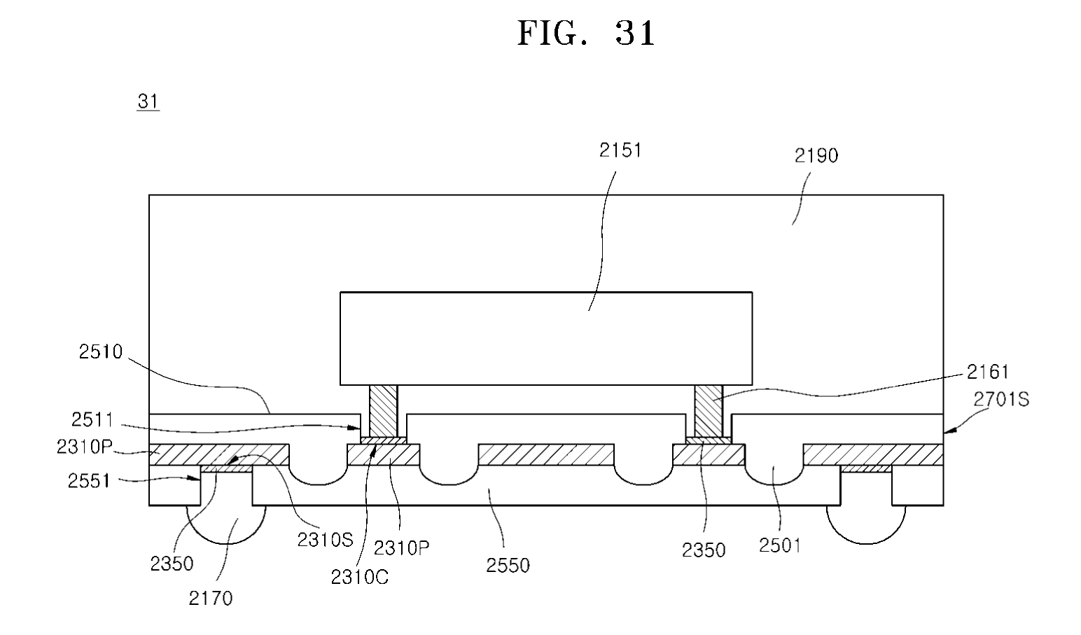

FIG. 31 is a cross-sectional view illustrating a semiconductor package 31 including the package substrate 2701S according to an embodiment.

Referring to FIG. 31, the semiconductor package 31 may include the package substrate 2701S and a semiconductor device 2151 mounted on the package substrate 2701S. The semiconductor device 2151 may be electrically connected to the package substrate 2701S through connection bumps 2161.

The package substrate 2701S may have the same configuration as the package substrate formed by the method described with reference to FIGS. 19 to 29. Accordingly, the package substrate 2701S may include the isolation wall portion 2501 protruding from a surface of the first front side dielectric layer 2510. Another surface of the first front side dielectric layer 2510 opposite to the isolation wall portion 2501 may be substantially flat.

The circuit patterns 2310P may be disposed in circuit trenches defined by the isolation wall portion 2501. As described with reference to FIG. 26, the top surfaces of the circuit patterns 2310P may be located at a level which is lower than the top surface (2502 of FIG. 26) of the isolation wall portion 2501. Thus, the circuit patterns 2310P may be disposed to have an embedded pattern shape. That is, the circuit patterns 2310P may be embedded in or covered with a dielectric layer including the first front side dielectric layer 2510 and the second dielectric layer 2550. Accordingly, the package substrate 2701S may be a substrate including embedded patterns.

The isolation wall portion 2501 may be disposed between the circuit patterns 2310P and may protrude from the top surfaces of the circuit patterns 2310P. Thus, the isolation wall portion 2501 may function as a barrier that improves an electrical insulation characteristic between the circuit patterns 2310P or suppresses a metal migration phenomenon between the circuit patterns 2310P. Since an electrical and physical isolation characteristic of the circuit patterns 2310P is improved due to the presence of the isolation wall portion 2501, a pitch size of the circuit patterns 2310P may be reduced.

The package substrate 2701S may further include the second dielectric layer 2550 covering the circuit patterns 2310P. The second dielectric layer 2550 may extend to cover a top surface and upper sidewalls of the isolation wall portion 2501 as well as top surfaces of the circuit patterns 2310P. Accordingly, the package substrate 2701S may be realized to include the circuit patterns 2310P that are located at the same level and embedded in a dielectric layer comprised of the first front side dielectric layer 2510 and the second dielectric layer 2550.

The first front side dielectric layer 2510 may include the third openings 2511 that expose some portions of the front side surfaces of the circuit patterns 2310P, and the portions of the circuit patterns 2310P exposed by the third openings 2511 may act as the first connectors 2310C. The exposed surfaces of the first connectors 2310C may be covered with the oxidation resistant layer 2350. The second dielectric layer 2550 may include the fourth openings 2551 that expose some portions of the back side surfaces of the circuit patterns 2310P, and the portions of the circuit patterns 2310P exposed by the fourth openings 2551 may act as the second connectors 2310S. The exposed surfaces of the second connectors 2310S may also be covered with the oxidation resistant layer 2350.

The connection bumps 2161 may be bonded to the first connectors 2310C to electrically connect the first connectors 2310C (i.e., the package substrate 2701S) to the semiconductor device 2150. The external connection members 2170 may be attached to the second connectors 2310S to electrically connect the semiconductor package 31 to, for example but not limited to, an external electronic device, an external semiconductor device, an external substrate or an external module. The external connection members 2170 may be solder balls. The protection layer 2190 may be disposed to cover the semiconductor device 2150. The protection layer 2190 may include an epoxy molding compound (EMC) material.

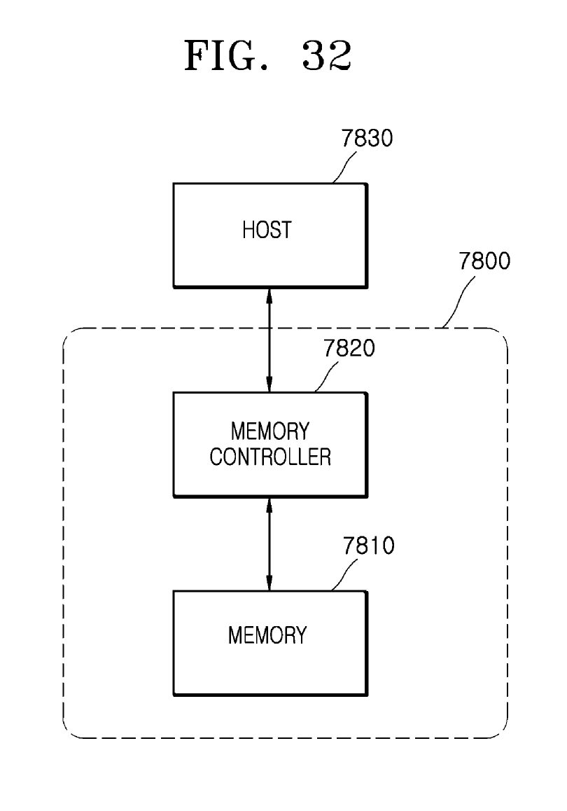

FIG. 32 is a block diagram illustrating an example of a representation of an electronic system including a memory card 7800 including at least one semiconductor package according to an embodiment. The memory card 7800 may include a memory 7810, such as a nonvolatile memory device, and a memory controller 7820. The memory 7810 and the memory controller 7820 may store data or read stored data. The memory 7810 and/or the memory controller 7820 include one or more semiconductor chips disposed in an embedded package according to an embodiment.

The memory 7810 may include a nonvolatile memory device to which the technology of the embodiments of the present disclosure may be applied. The memory controller 7820 may control the memory 7810 such that stored data is read out or data is stored in response to a read/write request from a host 7830.

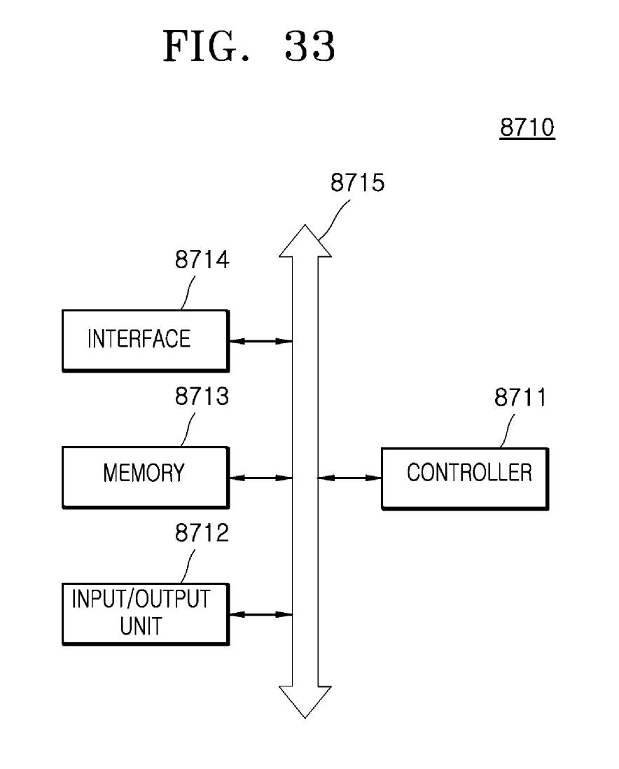

FIG. 33 is a block diagram illustrating an electronic system 8710 including at least one package according to an embodiment. The electronic system 8710 may include a controller 8711, an input/output unit 8712, and a memory 8713. The controller 8711, the input/output unit 8712 and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to embodiments of the present disclosure. The input/output unit 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system such as, for example but not limited to, CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A method of fabricating a package substrate, the method comprising:
forming an isolation trench in a conductive layer;
forming a first dielectric layer on the conductive layer to provide an isolation wall portion filling the isolation trench;
recessing the conductive layer to form circuit patterns in circuit trenches defined and separated by the isolation wall portion;
forming a second dielectric layer covering the circuit patterns; and
patterning the first and second dielectric layers to expose portions of the circuit patterns,
wherein the exposed portions of the circuit patterns act as connectors.

2. The method of claim 1, wherein forming the isolation trench includes etching a portion of the conductive layer by a thickness which is less than a thickness of the conductive layer.

3. The method of claim 1, wherein forming the isolation trench includes:
forming a first etch mask on the conductive layer to expose a portion of the conductive layer;
wet-etching the exposed portion of the conductive layer by a thickness which is less than a thickness of the conductive layer; and
removing the first etch mask.

4. The method of claim 1, wherein recessing the conductive layer to form the circuit patterns includes etching back the conductive layer to expose an upper portion of the isolation wall portion.

5. The method of claim 4,
wherein the upper portion of the isolation wall portion is formed to have a convex portion; and
wherein etching back the conductive layer is performed to expose the convex portion and upper sidewalls of the isolation wall portion.

6. The method of claim 1,
wherein the connectors includes first connectors and second connectors; and
wherein patterning the first and second dielectric layers includes:
removing portions of the first dielectric layer to expose first portions of the circuit patterns; and
removing portions of the second dielectric layer to expose second portions of the circuit patterns,
wherein the exposed first portions of the circuit patterns correspond to the first connectors and the exposed second portions of the circuit patterns correspond to the second connectors, and
wherein the first connectors are opened toward a first direction and the second connectors are opened toward a second direction opposite to the first direction.

7. A method of fabricating a package substrate, the method comprising:
forming a conductive layer on a front side surface and a back side surface of a carrier layer;
forming an isolation trench in the conductive layer;
forming a first dielectric layer on the conductive layer to provide an isolation wall portion filling the isolation trench;
separating a stack structure including the conductive layer and the first dielectric layer sequentially stacked on each of the front and back side surfaces of the carrier layer from the carrier layer;
recessing the conductive layer of the stack structure to form circuit patterns in circuit trenches defined and separated by the isolation wall portion;
forming a second dielectric layer covering the circuit patterns; and
patterning the first and second dielectric layers to expose portions of the circuit patterns,
wherein the exposed portions of the circuit patterns act as connectors.

8. The method of claim 7,
wherein the connectors include first connectors and second connectors; and
wherein patterning the first and second dielectric layers includes:
removing portions of the first dielectric layer to expose first portions of the circuit patterns; and
removing portions of the second dielectric layer to expose second portions of the circuit patterns,
wherein the exposed first portions of the circuit patterns correspond to the first connectors and the exposed second portions of the circuit patterns correspond to the second connectors, and
wherein the first connectors are opened toward a first direction and the second connectors are opened toward a second direction opposite to the first direction.

9. The method of claim 7, wherein the carrier layer is provided to include a copper clad laminate (CCL) structure.

10. The method of claim 7, wherein forming the isolation trench includes etching a portion of the conductive layer by a thickness which is less than a thickness of the conductive layer.

11. The method of claim 7, wherein forming the isolation trench includes:
forming a first etch mask on the conductive layer to expose a portion of the conductive layer;
wet-etching the exposed portion of the conductive layer by a thickness which is less than a thickness of the conductive layer; and
removing the first etch mask.

12. The method of claim 7, wherein recessing the conductive layer to form the circuit patterns includes etching back the conductive layer to expose an upper portion of the isolation wall portion.

13. The method of claim 12,
wherein the upper portion of the isolation wall portion is formed to have a convex portion; and
wherein etching back the conductive layer is performed to expose the convex portion and upper sidewalls of the isolation wall portion.

14. The method of claim 7,
wherein the connectors include first connectors and second connectors; and
wherein patterning the first and second dielectric layers includes:
removing portions of the first dielectric layer to expose first portions of the circuit patterns; and
removing portions of the second dielectric layer to expose second portions of the circuit patterns,
wherein the exposed first portions of the circuit patterns correspond to the first connectors and the exposed second portions of the circuit patterns correspond to the second connectors, and
wherein the first connectors are opened toward a first direction and the second connectors are opened toward a second direction opposite to the first direction.
